(19) United States
(12) Patent Application Publication
(10) Pub. No.: US 2016/0246529 A1
(43) Pub. Date: Aug. 25, 2016

(54) STORAGE DEVICE AND OPERATING METHOD OF THE SAME

(71) Applicant: Samsung Electronics Co., Ltd., Suwon-si (KR)

(72) Inventors: Wooram KIM, Siheung-si (KR); Jinhyuk KIM, Hwaseong-si (KR); MoonSang KWON, Seoul (KR)

(21) Appl. No.: 14/959,131

(22) Filed: Dec. 4, 2015

(30) Foreign Application Priority Data
Feb. 23, 2015 (KR) 10-2015-0025294

(51) Int. Cl. G06F 3/06; G11C 16/16

(52) U.S. Cl. CPC G06F 3/0623; G11C 16/16; G06F 3/064; G06F 3/0679

(57) ABSTRACT

An operating method of a storage device including a nonvolatile memory device includes receiving a logical address and a write command for first data from an external device, determining whether the write command includes security properties, detecting whether second data written into the same logical address as the logical address exists according to a result of the determination, and writing the first data into a unit memory area in which the second is stored according to a result of the detection.

### CROSS-REFERENCE TO RELATED APPLICATIONS

This U.S. non-provisional patent application claims the benefit of priority under 35 USC §119 to Korean Patent Application No. 10-2015-0025294, filed on Feb. 23, 2015, in the Korean Intellectual Property Office, the disclosure of which is hereby incorporated in its entirety by reference.

### BACKGROUND

Various example embodiments relate to semiconductor memory devices and, more particularly, to storage devices providing high security performance and/or operating methods of the storage devices.

Semiconductor memory devices are typically implemented using semiconductors such as silicon (Si), germanium (Ge), gallium arsenide (GaAs), and indium phosphide (InP). In general, semiconductor memory devices are classified into volatile memory devices and nonvolatile memory devices.

Volatile memory devices lose their stored data when their power supplies are interrupted. Volatile memory devices include static RAM (SRAM), dynamic RAM (DRAM), synchronous DRAM (SDRAM), and the like. Nonvolatile memory devices retain their stored data even when their power supplies are interrupted. Nonvolatile memory devices include read only memory (ROM), programmable ROM (PROM), electrically programmable ROM (EPROM), electrically erasable and programmable ROM (EEPROM), flash memory, phase-change RAM (PRAM), resistive RAM (RRAM), ferroelectric RAM (FRAM), and the like.

A nonvolatile storage device is fabricated using nonvolatile memory. The nonvolatile storage device includes a nonvolatile memory and a memory controller that accesses the nonvolatile memory and communicates with an external host device. The nonvolatile storage device may be embedded in various mobile devices such as smartphones, tablets, USB drives, etc., and may also be implemented in the form of products such as solid state drives (SSD).

Data having various properties are stored in such nonvolatile storage devices. However, much time is required to fully erase data with a high level of security. This is because overwrite operations cannot be performed on nonvolatile memory devices, and instead nonvolatile memory devices are required to perform data updates by writing the updated data at a new memory address location on the nonvolatile storage device. The update is completed by updating the memory address mapping information for the data written at the new memory location. Therefore, when the corresponding data is erased, the data previously written at the previous memory location may remain although the most recently written data is erased. Accordingly, there is a need for an erase method and/or a processing method for efficiently and completely erasing data that may remain due to a data update operation in order to ensure the security of data stored on nonvolatile storage devices.

### SUMMARY

Various example embodiments relate to storage devices and/or operating methods of the storage devices.

An operating method of a storage device including a nonvolatile memory device according to at least one example embodiment of the inventive concepts may include receiving a logical address corresponding to the nonvolatile memory device and a write command for first data from an external device, determining whether the write command includes at least one security property, detecting whether second data is stored in the received logical address of the nonvolatile memory device, based on a result of the determination, and writing the first data into a unit memory area of the nonvolatile memory device in which the second data is stored, based on a result of the detection.

At least one example embodiment of the operating method may include wherein the unit memory area corresponds to an erase-unit memory area of the nonvolatile memory device.

At least one example embodiment of the operating method may include wherein the erase-unit memory area corresponds to a memory block of the nonvolatile memory device.

At least one example embodiment of the operating method may include the first data is data to update the second data, and the second data is invalidated.

At least one example embodiment of the operating method may include receiving an erase command for the first data from the external device.

At least one example embodiment of the operating method may include performing a block erase operation on the erase-unit memory area of the nonvolatile memory device in response to the receiving the erase command for the first data.

At least one example embodiment of the operating method may include wherein the erase command includes information to indicate at least one security property.

At least one example embodiment of the operating method may include wherein the nonvolatile memory device includes a separate secure memory area configured to store the first data or the second data.

At least one example embodiment of the operating method may include wherein the first data is written into an arbitrary programmable memory block of the nonvolatile memory device when the write command does not include the at least one security property.

At least one example embodiment of the operating method may include wherein the nonvolatile memory device includes a three-dimensional memory array, the three-dimensional memory array including a charge trap layer.

A storage device according to at least one example embodiment of the inventive concepts may include a nonvolatile memory device, and a memory controller configured to control the nonvolatile memory device, the memory controller is configured to store and update data write-requested and update-requested by a secure write command from an external device using a logical address corresponding to the nonvolatile memory device, and perform a block erase operation on the memory block of the nonvolatile memory device in response to an erase command for the data.

At least one example embodiment of the storage device may include wherein the erase command is a secure erase command to erase data including at least one security property.

At least one example embodiment of the storage device may include wherein the memory block is erased on the nonvolatile memory device in response to the erase command for the data without performing garbage collection.

At least one example embodiment of the storage device may include wherein the nonvolatile memory device includes a plurality of three-dimensionally stacked memory blocks.

An operating method of a storage device including a nonvolatile memory device according to at least one example embodiment of the inventive concepts may include receiving a logical address and a secure write command for first data from an external device, detecting whether there is second data stored on the nonvolatile memory device using the secure write command at the received logical address of the nonvolatile memory device, generating link information including a physical address of the second data on the nonvolatile memory device according to a result of the detection, and writing the first data into a memory block corresponding to the logical address on the nonvolatile memory device.

A nonvolatile storage device according to at least one example embodiment of the inventive concepts may include a nonvolatile memory device, and a memory controller configured to receive at least one data operation command and a logical address associated with the at least one command from an external device, the at least one data operation command and the logical address related to the nonvolatile memory device, determine whether the received at least one data operation command indicates that a secure data operation is requested, and perform the secure data operation at the received logical address of the nonvolatile memory device in accordance with the results of the determination.

At least one example embodiment of the nonvolatile storage device may include wherein the nonvolatile memory device further includes at least one secure memory block area and at least one non-secure memory block area, and the secure data operation includes at least one of a secure write command, a secure update command, and a secure erase command.

At least one example embodiment of the nonvolatile storage device may include wherein the memory controller is further configured to determine whether the secure data operation is a secure write command or a secure update command by determining whether the received logical address corresponds to a previously received logical address related to a secure write command.

At least one example embodiment of the nonvolatile storage device may include wherein the memory controller is further configured to receive data from the external device corresponding to the received at least one data operation command when the received at least one data operation command is a secure write command or a secure update command, write the received data in the at least one secure memory block area, and update a memory address mapping history associated with the memory controller with a physical location of the data written in the at least one secure memory block area.

At least one example embodiment of the nonvolatile storage device may include wherein the memory controller is further configured to receive data from the external device corresponding to the received at least one data operation command when the received at least one data operation command is a secure update command, write the received data in the at least one secure memory block area, erase data stored at a previous physical address associated with the received logical address, and update a memory address mapping history associated with the memory controller with a new physical location of the data written in the at least one secure memory block area.

At least one example embodiment of the nonvolatile storage device may include wherein the memory controller is further configured to erase data corresponding to the received logical address from the at least one secure memory block area when the secure data operation is a secure erase command, and update a memory address mapping history associated with the memory controller in accordance with the results of the erase operation.

According to some example embodiments of the inventive concepts, data updated several times may be erased at high speed by receiving a command only once. Thus, a storage device may be provided with high efficiency and high security performance for data that requires high security properties.

### BRIEF DESCRIPTION OF THE DRAWINGS

The forgoing and other features of inventive concepts will be described below in more detail with reference to the accompanying drawings of non-limiting example embodiments of inventive concepts in which like reference characters refer to like parts throughout the different views. The drawings are not necessarily to scale, emphasis instead being placed upon illustrating principles of inventive concepts. In the drawings:

FIG. 1 is a block diagram of a storage device according to at least one example embodiment of the inventive concepts;

FIG. 2 is a flowchart summarizing a secure write operation performed by a memory controller in FIG. 1 according to at least one example embodiment of the inventive concepts;

FIG. 3 is a flowchart summarizing a secure erase operation performed by the memory controller in FIG. 1 according to at least one example embodiment of the inventive concepts;

FIG. 4 illustrates a method of writing data by a secure write command according to at least one example embodiment of the inventive concepts;

FIG. 5 illustrates a secure erase operation according to at least one example embodiment of the inventive concepts;

FIG. 6 is a block diagram of a storage device according to at least one example embodiment of the inventive concepts;

FIG. 7 is a block diagram of a storage device according to at least one example embodiment of the inventive concepts;

FIG. 8 is a flowchart summarizing a secure write operation performed by a memory controller in FIG. 7 according to at least one example embodiment of the inventive concepts;

FIGS. 9A and 9B illustrate a data management method described in FIG. 8 according to at least one example embodiment of the inventive concepts;

FIG. 10 is a block diagram of a storage device according to at least one example embodiment of the inventive concepts;

FIG. 11 is a flowchart summarizing a write operation performed by a memory controller in FIG. 10 according to at least one example embodiment of the inventive concepts;

FIG. 12 is a flowchart summarizing a secure erase operation performed by the memory controller in FIG. 10 according to at least one example embodiment of the inventive concepts;

FIG. 13 illustrates a data management method described in FIGS. 11 and 12 according to at least one example embodiment of the inventive concepts;

FIG. 14 is a block diagram of a storage device according to at least one example embodiment of the inventive concepts;

FIG. 15 is a flowchart summarizing a write operation performed in the storage device in FIG. 14 according to at least one example embodiment of the inventive concepts;

FIG. 16 is a flowchart summarizing a secure erase operation performed in the storage device in FIG. 14 according to at least one example embodiment of the inventive concepts;

FIG. 17 illustrates a data management method described in FIGS. 15 and 16 according to at least one example embodiment of the inventive concepts;

FIG. 18 shows data generated at the memory controller in FIG. 14 through encoding using link information according to at least one example embodiment of the inventive concepts;

FIG. 19 is a block diagram of a system according to at least one example embodiment of the inventive concepts;

FIGS. 20A and 20B illustrate memory blocks having the form of a three-dimensional cell array included in the nonvolatile memory devices in FIGS. 1, 6, 7, 10, and 14 according to at least one example embodiment of the inventive concepts;

FIG. 21 is a block diagram of a memory card system to which a nonvolatile memory system according to at least one example embodiment of the inventive concepts;

FIG. 22 is a block diagram of a solid state drive (SSD) system to which a nonvolatile memory system according to at least one example embodiment of the inventive concepts; and

FIG. 23 is a block diagram of a user system to which a nonvolatile memory system according to at least one example embodiment of the inventive concepts.

### DETAILED DESCRIPTION

Various example embodiments will now be described more fully with reference to the accompanying drawings, in which some example embodiments are shown. Example embodiments, may, however, be embodied in many different forms and should not be construed as being limited to the embodiments set forth herein; rather, these example embodiments are provided so that this disclosure will be thorough and complete, and will fully convey the scope of example embodiments of inventive concepts to those of ordinary skill in the art. In the drawings, the thicknesses of layers and regions are exaggerated for clarity. Like reference characters and/or numerals in the drawings denote like elements, and thus their description may be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements or layers should be interpreted in a like fashion (e.g., “between” versus “directly between,” “adjacent” versus “directly adjacent,” “on” versus “directly on”). As used herein the term “and/or” includes any and all combinations of one or more of the associated listed items.

It will be understood that, although the terms “first”, “second”, etc. may be used herein to describe various elements, components, regions, layers and/or sections. These elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof. Expressions such as “at least one of,” when preceding a list of elements, modify the entire list of elements and do not modify the individual elements of the list.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

In example embodiments, a nonvolatile memory may be embodied to include a three dimensional (3D) memory array. The 3D memory array may be monolithically formed on a substrate (e.g., semiconductor substrate such as silicon, or semiconductor-on-insulator substrate). The 3D memory array may include two or more physical levels of memory cells having an active area disposed above the substrate and circuitry associated with the operation of those memory cells, whether such associated circuitry is above or within such substrate. The layers of each level of the array may be directly deposited on the layers of each underlying level of the array.

In example embodiments, the 3D memory array may include vertical NAND strings that are vertically oriented such that at least one memory cell is located over another memory cell. The at least one memory cell may comprise a charge trap layer.

The following patent documents, which are hereby incorporated by reference in their entirety, describe suitable configurations for three-dimensional memory arrays, in which the three-dimensional memory array is configured as a plurality of levels, with word lines and/or bit lines shared between levels: U.S. Pat. Nos. 7,679,133; 8,553,466; 8,654,587; 8,559,235; and US Pat. Pub. No. 2011/0233648.

Below, various example embodiments will be described using flash memory device(s) as a nonvolatile storage media. However, the example embodiments are not limited to only flash memory devices. Rather, nonvolatile storage media within at least one example embodiment may be formed using other types of nonvolatile memory devices such as PRAM, MRAM, ReRAM, FRAM, NOR flash memory, etc.

Throughout the specification, the terms “updating data” and “updated data” is in reference to modifying data having the same logical address. In addition, the term “invalid data” refers to data that is erased on a map but exists in a nonvolatile memory device, while the term “valid data” refers to unerased data.

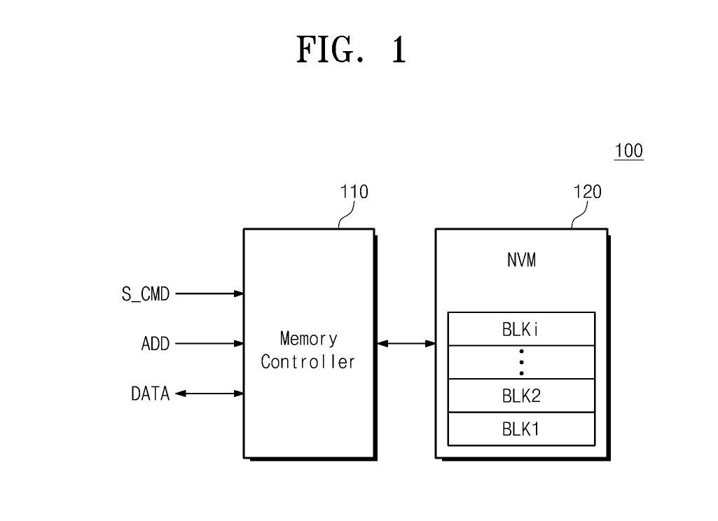

FIG. 1 is a block diagram of a storage device 100 according to some example embodiments of the inventive concepts. As illustrated, the storage device 100 includes a memory controller 110 and a nonvolatile memory device 120.

The memory controller 110 may be configured to control the nonvolatile memory device 120 in response to a request of a host (not shown). The memory controller 110 interfaces with the host and the nonvolatile memory device 120. The memory controller 110 accesses a selected memory block of the nonvolatile memory device 120 in response to the request of the host. The host request may include one or more of a secure command (S_CMD), a memory address (ADD), and/or data to be written at the memory address (DATA), etc.

The memory controller 110 may program data into a memory block of the nonvolatile memory device 120 or erase programmed data in response to various access requests of the host. Particularly, the memory controller 110 may write data into a selected memory block or erase written data in response to a secure command S_CMD from the host. For example, the secure command S_CMD may include a secure write command S_Write or a secure erase command S_Erase, etc.

The memory controller 110 controls the nonvolatile memory device 120 to write write-request data (e.g., DATA) into a specific and/or desired block (e.g., the address represented by the ADD signal) in response to the secure write command S_Write from the host. For example, when receiving a request from the host to write first data according to the secure write command S_Write, the memory controller 110 may write the first data into a secure memory block. When receiving a request from the host to update the first data, the memory controller 110 may write update data into the secure memory block. That is, the memory controller 110 may write data to the same logical address write-requested with the secure write command S_Write into the same memory block. The logical address may be the address represented by the ADD signal, or another address supplied with the S_Write signal.

The memory controller 110 controls the nonvolatile memory device 120 to perform a block erase operation on a secure block in which the erase-requested data is stored, in response to the secure erase command S_Erase from the host. That is, the memory controller 110 controls the nonvolatile memory device 120 to erase the latest data to all invalid data corresponding to the same logical address in response to the secure erase command S_Erase. The logical address may be the address represented by the ADD signal, or another address supplied with the S_Erase signal. Through the secure erase operation, when security-required data is erased, all invalid data may be erased by a block erase operation of a memory block in which the corresponding data is stored.

The nonvolatile memory device 120 performs erase, read, and write, etc., operations according to the control of the memory controller 110. The nonvolatile memory device 120 may include a plurality of memory blocks BLK1 to BLKi each including a plurality of memory cells arranged in rows, columns, and/or layers. Each of the memory blocks BLK1 to BLKi constitute a single erase unit. The nonvolatile memory device 120 may write write-requested data into a corresponding block or perform a block erase operation on an erase-requested memory block according to a command and a control signal provided from the memory controller 110.

The nonvolatile memory device 120 may include memory blocks formed of a three-dimensional (3D) memory array. The 3D memory array is monolithically formed in one or more physical levels of arrays of memory cells having an active area disposed above a silicon substrate and circuitry associated with the operation of those memory cells, whether such associated circuitry is above or within such substrate. The term “monolithic” means that layers of each level of the array are directly deposited on the layers of each underlying level of the array.

In at least one example embodiment of the present inventive concepts, the 3D memory array includes vertical NAND strings that are vertically oriented such that at least one memory cell is located over another memory cell. The at least one memory cell may comprise a charge trap layer. Each vertical NAND string may include at least one select transistor located over memory cells, the at least one select transistor having the same structure with the memory cells and being formed monolithically together with the memory cells.

According to the above-described storage device 100, the memory controller 110 may receive a secure command S_CMD including hint information (e.g., at least one secure property) from the host. The secure command S_CMD includes a secure write command S_Write and a secure erase command S_Erase. The memory controller 110 writes data of the same logical address to the same memory block in response to the secure write command S_Write from the host. When receiving the secure erase command S_Erase, the memory controller 110 may perform a block erase operation on a memory block in which corresponding data is stored. Thus, all data corresponding to the same address provided by the secure write command S_Write may be fully erased in the nonvolatile memory device 120 by the secure erase command S_Erase.

During a secure erase operation, data that needs to be retained through garbage collection does not exist in an erased memory block. Thus, an additional operation such as page copy and garbage collection does not occur to process secure data. According to the storage device 100, a separate garbage collection count or block erase count may significantly decrease during a memory management operation performed to ensure secure properties. Thus, the storage device 100 may provide high security performance, improve memory operating speed, and decrease a block erase count to extend the lifetime of a nonvolatile memory device.

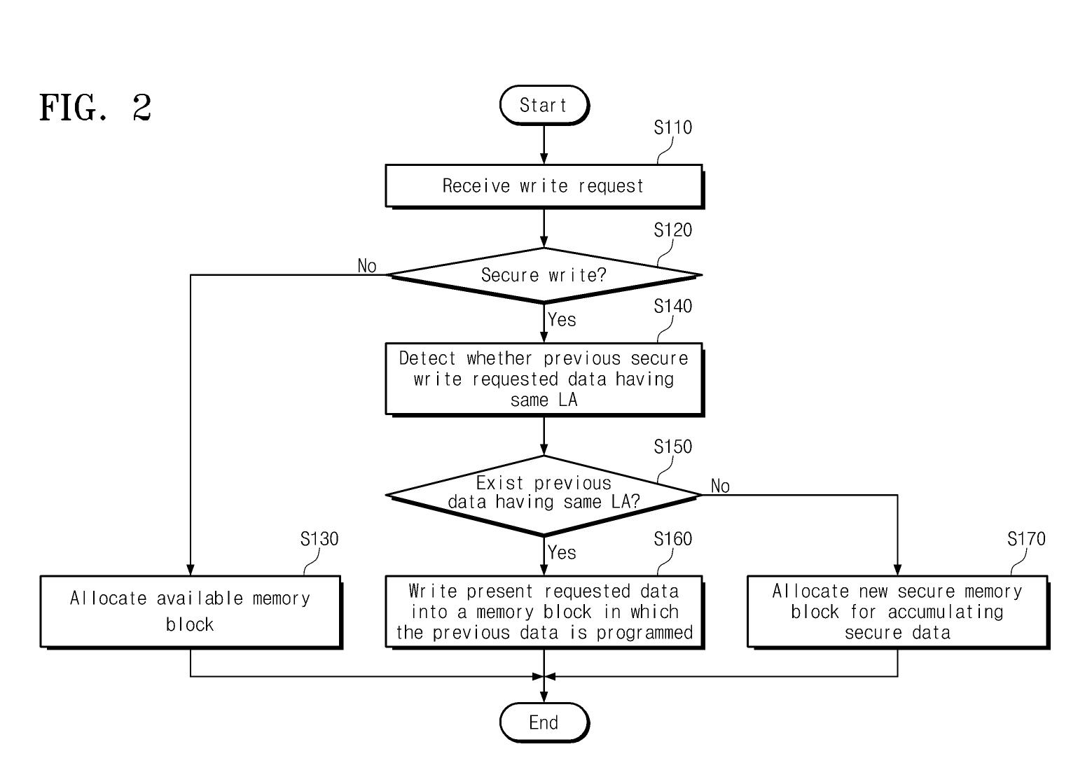

FIG. 2 is a flowchart summarizing a secure write operation performed by the memory controller 110 in FIG. 1, according to at least one example embodiment. The memory controller 110 may perform the secure write operation in response to a command provided from the host.

The memory controller 110 may receive a write request from the host (S110). The host may determine whether the write request is a secure write request or a normal write request according to at least one property of data to be write-requested. According to the result of the determination, the host may transmit a write command to the memory controller 110. For example, the host may request to write data, which must be managed in a secure mode, using a secure write command S_Write. Additionally, the host may request to write data, which need not be managed in the secure mode, using a normal write command Write (e.g., a non-secure write operation). For example, the secure write command S_Write may be differentiated by adding bits that define additional command properties from the normal write command Write.

The memory controller 110 may detect properties of a write command to perform an operation branch. When the write command is not the secure write command S_Write (No direction), the flow proceeds to S130. When the write command corresponds to the secure write command S_Write (Yes direction), the flow proceeds to S140.

The memory controller 110 may control the nonvolatile memory device 120 to write the write-requested data into a memory block corresponding to an input logical address LA (S130). The memory controller 110 may provide a command, data, an address, etc. to the nonvolatile memory device 120 to program the write-requested data into a memory block mapped to the logical address LA provided with the write command.

The memory controller 110 determines whether write-requested data in a secure mode is initial input data or data to update previous input data (S140). When the write-requested data is the data to update the previous input data, logical addresses LA of the previous input data and the current input data may be identical to each other. That is, the memory controller 110 may determine whether there is data having the same logical address as a logical address of current write-requested data among the previous write-requested data. The determination may be made with reference to address mapping information managed by the memory controller 110.

The memory controller 110 performs the operation branch according to the result of determination of whether the current write-requested data is data to update the previous data (S150). For example, when there are previous write-requested data having the same logical address as the current write-requested data (Yes direction), the flow proceeds to S160. When there is no previous write-requested data having the same logical address as the current write-requested data (No direction), the flow proceeds to S170.

The memory controller 110 may control the nonvolatile memory device 120 to program the current write-requested data into a memory block in which the data having the same logical address as the previous write-requested data is stored (S160). The memory controller 110 may write the write-requested data into a secure memory block in which the write-requested data in the secure mode is stored.

The memory controller 110 may allocate a new secure memory block because there is no data having the same logical address among the data managed as valid data although the write-requested data is write-requested in the secure mode (S170). Through the allocation of the new secure memory block, the data having the same logical address may be managed in the secure mode.

Hitherto, the description has been concerned with the operation of the storage device 100 when a write command provided from the host includes hint information regarding secure properties. That is, in case of data in which the secure properties are defined, the storage device 110 may store data having the same logical address in a memory area of the same erase unit.

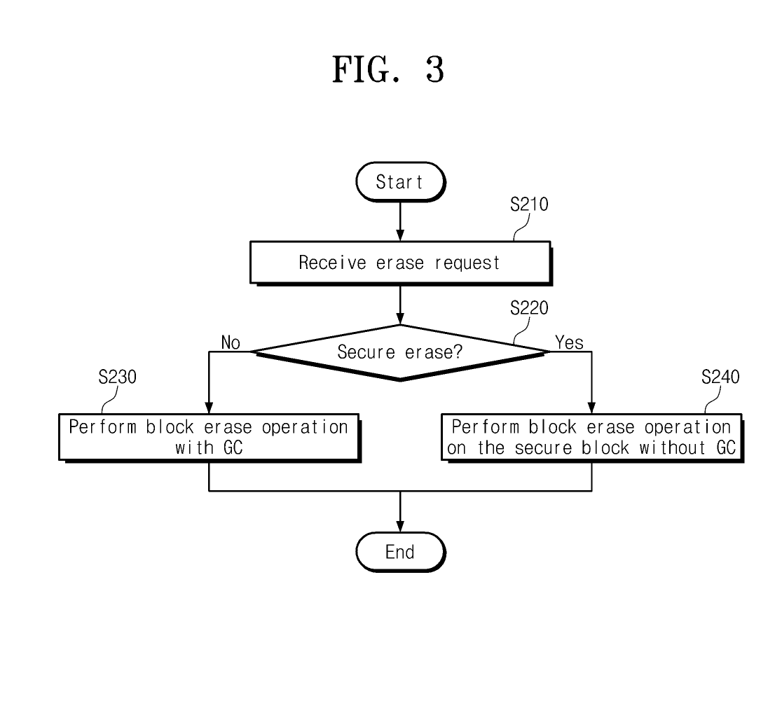

FIG. 3 is a flowchart summarizing a secure erase operation performed by the memory controller 110 in FIG. 1, according to at least one example embodiment. The memory controller 110 may perform the secure write operation in response to a command provided from the host.

The memory controller 110 may receive an erase request from the host (S210). The host may determine whether the erase request is a secure erase request or a normal erase request (e.g., non-secure erase request) according to at least one property regarding the specific and/or desired data when the specific and/or desired data is erase-requested. For example, when secure-requested data such as a security/secure key is erased in a normal erase mode, the secure-requested data may not be fully erased in the nonvolatile memory device 120. This is because when a security/secure key that is frequently updated is erased using a normal erase command, only the latest (e.g., last stored) security/secure key is erased and the previous security/secure key data may still exist at other memory addresses (e.g., memory blocks) in the nonvolatile memory device 120. The host may selectively transmit a secure erase command S_Erase or a normal erase command Erase according to the properties of such data to be erased, such as whether the data must be fully erased from the nonvolatile memory device like security keys.

The memory controller 110 detects properties of an erase command to perform operation branch. When the erase command is not the secure erase command S_Erase (No direction), the flow proceeds to S230. When the erase command corresponds to the secure erase command S_Erase (Yes direction), the flow proceeds to S240.

The memory controller 110 may perform garbage collection (GC) to erase erase-requested data (S230). There may be valid data in a memory block in which the erase-requested data is stored. The memory controller 110 may control the nonvolatile memory device 120 to perform a block erase operation on the memory block in which the erase-requested data is stored, after copying the valid data to another memory block. It will be understood that in such a normal erase operation, data invalidated after being updated may not be erased although the erase-requested data is data to update previous data.

The memory controller 110 performs a secure erase operation to erase the erase-requested data in a secure mode (S240). The memory controller 110 may control the nonvolatile memory device 120 to perform a block erase operation on a memory block corresponding to a logical address LA included in the secure erase command. Invalid data having the same logical address as the erase-requested data stored in the secure memory block may be removed by performing the block erase operation once or more. Moreover, since there is no valid data in the secure memory block on the basis of a time point when the secure erase operation is required, page copy or garbage collection (GC) need not to be performed before the block erase operation.

Hitherto, the description has been concerned with the operation of the storage device 100 for a secure erase command provided from the host. That is, when the secure erase command is provided, data updated in a secure memory block may be erased by a block erase operation without previously performing garbage collection. Accordingly, there is no need for complex data handling and prolonged time required to erase the erase-requested data and valid data before being updated.

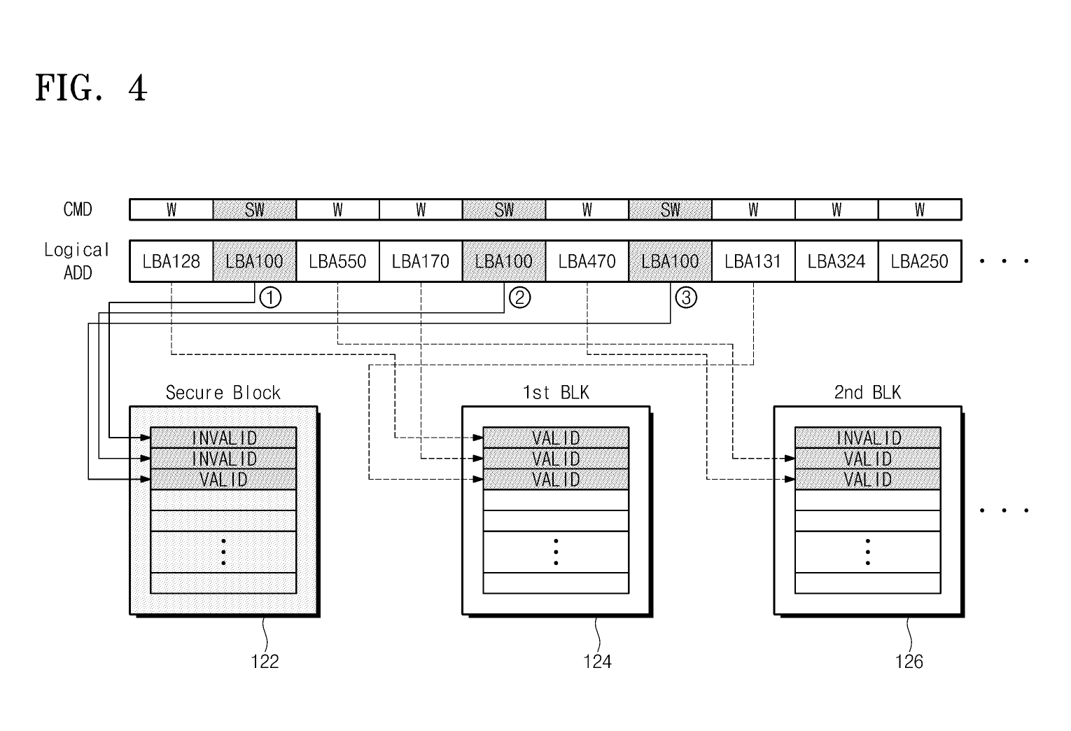

FIG. 4 illustrates a method for writing data by a secure write command according to at least one example embodiment of the inventive concepts. A command CMD and a logical address LA may be sequentially input from a host, and a secure write command SW may be disposed between normal write commands W. In FIG. 4, secure write commands W and corresponding logical addresses LA are shown in shading. Data write-requested by a secure write command SW may be stored in a secure memory block 122, and data write-requested by a normal write command W may be stored in memory blocks 124 and 126.

In a first example, a normal write command W and data write-requested by a logical address LBA128 may be stored in a first memory block 124. Data write-requested by the secure write command SW a logical address LBA100 may be stored in an uppermost write unit of the secure memory block 122. The procedure of storing the data write-requested by the secure write command SW is indicated by the line corresponding to the numeral “1”. The write unit may be a sector unit or a page unit.

Normal write commands W and data write-requested by logical addresses LBA550 and LBA170 are stored in the first memory block 124 and a second memory block 126, respectively. In a second example, the secure write command W and the logical address LBA100 are input. Due to the same logical address LBA100 as the data write-requested previously by the secure write command, a data write operation indicated by the line corresponding to the numeral “2” corresponds to a write operation to update the previously written data. Thus, previous data stored in the secure memory block 122 may be invalidated and updated data may be written into the same secure memory block 122.

A normal write command W and data write-requested by a logical address LBA470 are written into a write unit of the first memory block 124. In a third example, a write request by the secure write command SW and the logical address LBA100 are input. Due to the same logical address LBA100 as the data write-requested previously being used by the secure write command SW, a data write operation indicated by the line corresponding to the numeral “3” corresponds to a write operation to the third update of the previously written data. Thus, the previously written data stored in the secure memory block 122 may be invalidated and only the data stored third in the same secure memory block 122 may be validly managed.

Hitherto, the description has been concerned with a method of managing data write-requested and data update-requested by the secure write command SW and the same logical address LBA100. The data write-requested by the secure write command SW may be allocated to corresponding secure memory blocks depending on logical addresses, respectively. That is, data write-requested by the secure write command SW and a logical address LBA200 may be successively written into another secure memory block.

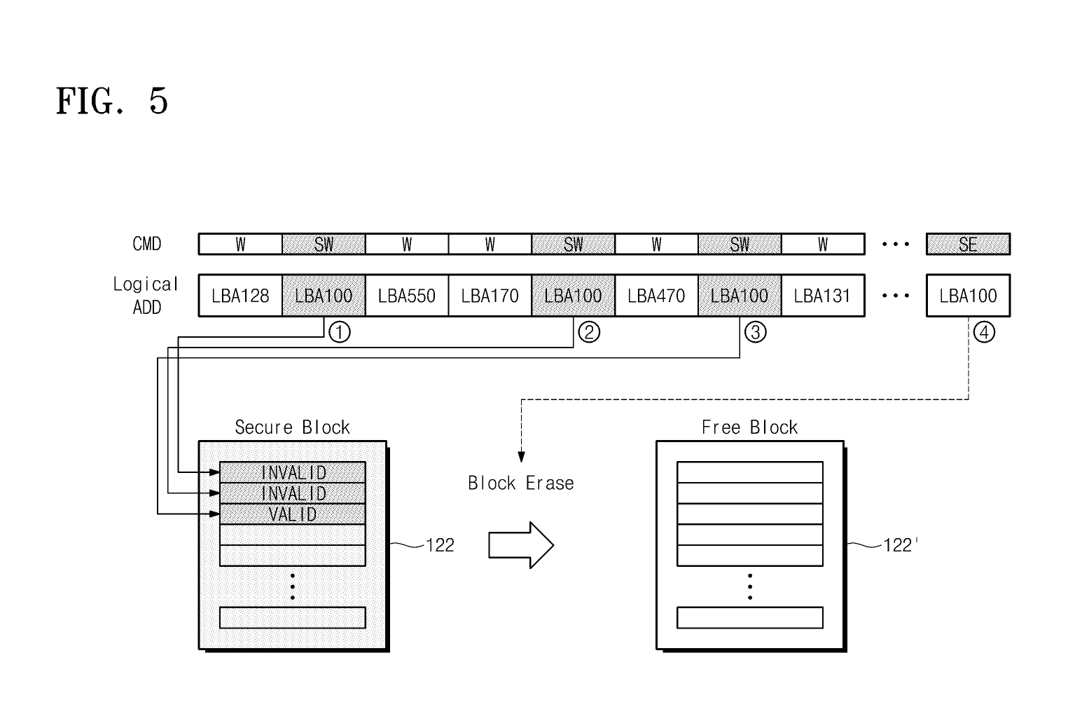

FIG. 5 illustrates a secure erase operation according to at least one example embodiment of the inventive concepts. Data write-requested by a secure write command SW and a logical address LBA100 are stored in a secure memory block 122 from a host. When data written by the same logical address LBA100 are all included in a single secure memory block 122, these data may be erased by the secure erase command SE without performing additional garbage collection.

As previously described with reference to FIG. 4, data write-requested by the secure write command SW and the logical address LBA100 are written into the secure memory block 122. Among the written data, the finally written data is in a valid state and previously written data are invalidly managed (e.g., marked as invalid by the memory controller 110). When a write request is provided by the secure write command SE and the logical address LBA, the memory controller 110 may control the nonvolatile memory device 120 to perform a block erase operation on the secure memory block 122. This procedure is indicated by the line corresponding to the numeral “4”. The erased secure memory block 122 may be allocated to a free block 122′.

According to the example embodiments described with reference to FIGS. 1 to 5, a storage device according to some example embodiments of the inventive concepts may manage secure data by secure write commands and/or secure erase commands provided from a host. That is, data provided with a secure write command S_Write and the same logical address may be intensively updated and/or written into a designated write unit. Additionally, when the data stored in the secure memory block is erase-requested by a secure erase command S_Erase, the memory controller 110 may control a nonvolatile memory device to perform a block erase operation on the secure memory block without performing garbage collection or a page copy operation. Through the above procedures, improved and/or increased security performance for secure data may be achieved, and the lifetime and operating speed of a nonvolatile memory device may be increased while also providing improved and/or increased security performance.

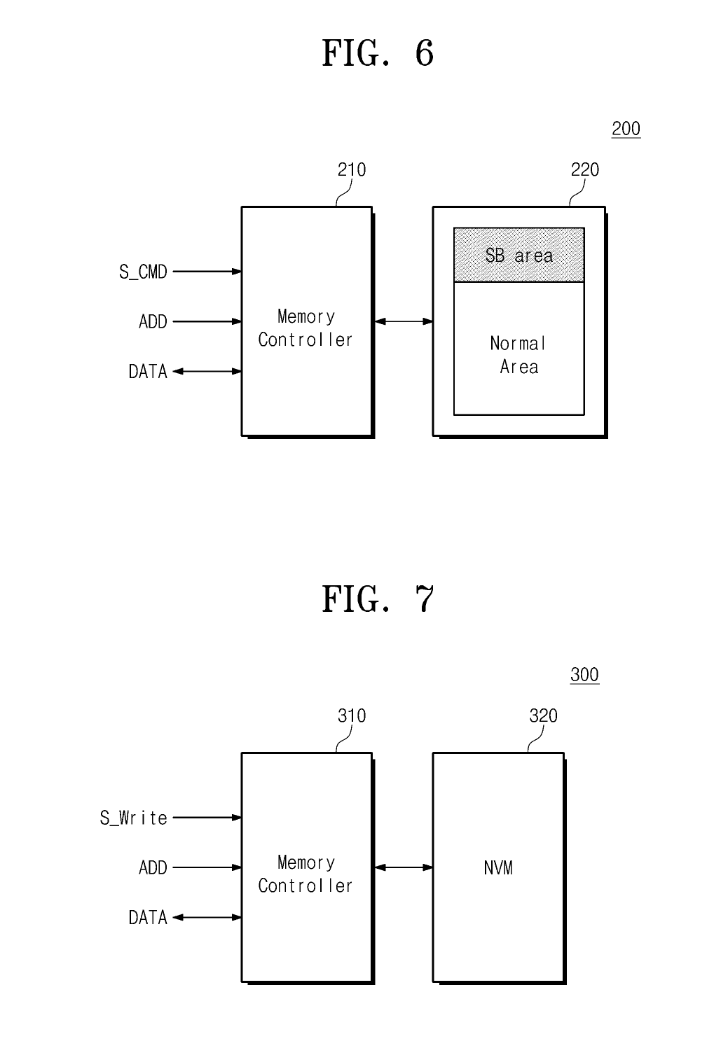

FIG. 6 is a block diagram of a storage device 200 according to at least one example embodiment of the inventive concepts. As illustrated, the storage device 200 may include a memory controller 210 and a nonvolatile memory device 220. In particular, the memory controller 210 may manage a storage area of the nonvolatile memory device 220 as a secure block (SB) area and a normal bock area.

The memory controller 210 may be configured to control the nonvolatile memory device 120 in response to a request of a host. The memory controller 210 may write data into a selected memory block or erase written/stored data in response to a secure command S_CMD from the host. For example, the secure command S_CMD may include a secure write command S_Write, a secure erase command S_Erase, a secure update command, etc.

The memory controller 210 may select a memory block of the secure block area and write write-requested data into the selected memory block in response to a secure write command S_Write from the host. For example, the memory controller 210 may select a memory block of the secure block area and write first data into the selected memory block when being requested from the host to write the first write data according to the secure write command S_Write. The memory controller 210 may write update data into the same memory block in which updated data exists when being requested to update the first data according to the secure write command S_Write.

The memory controller 210 controls the nonvolatile memory device 220 to perform a block erase operation on a memory block in which erase-requested data is stored, in response to a secure erase command S_Erase from the host. That is, the memory controller 210 controls the nonvolatile memory device 220 to erase all invalid data corresponding to a logical address in response to the secure erase command S_Erase. Through the secure erase operation, when security-requested data is erased, even invalid data may be erased by performing a block erase operation on the memory block in which the corresponding data is stored.

The nonvolatile memory device 220 performs erase, read, write, etc. operations according to the control of the memory controller 210. The nonvolatile memory device 220 may include a plurality of memory blocks BLK1 to BLKi each including a plurality of memory cells arranged in rows, columns, and/or layers. Each of the memory blocks BLK1 to BLKi may constitute a single erase unit. The nonvolatile memory device 220 may write write-requested data into a corresponding block or perform a block erase operation on the erase-requested memory block according to a command and a control signal provided from the memory controller 210.

During a secure erase operation according to some example embodiments of the inventive concepts, data that must be retained through garbage collection does not exist in an erased memory block. Thus, an additional operation such as a page copy operation and garbage collection does not occur when processing the secure data. According to the storage device 200, a separate garbage collection or block erase count may be significantly reduced during a management operation performed to ensure secure properties in accordance with at least one of the example embodiments of the inventive concepts. Thus, the storage device 200 may provide high security performance, improve memory operating speed, and decrease the block erase count to extend the lifetime of nonvolatile memory devices.

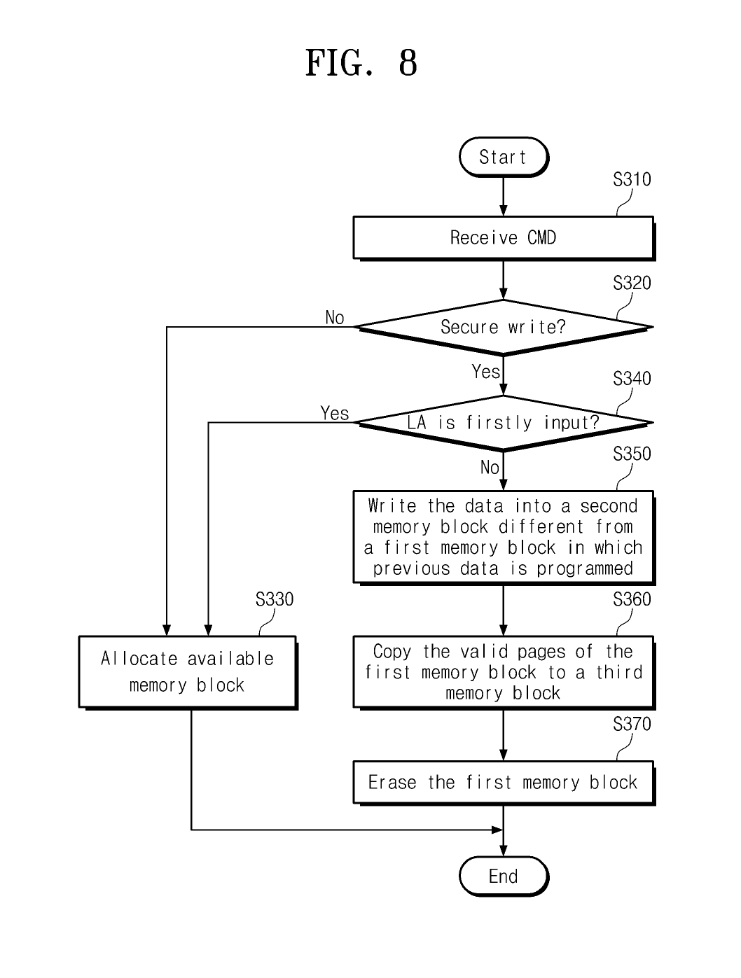

FIG. 7 is a block diagram of a storage device 300 according to at least one example embodiment of the inventive concepts. As illustrated, the storage device 300 may include a memory controller 310 and a nonvolatile memory device 320.

The memory controller 310 may program data into a memory block of the nonvolatile memory device 320 or erase programmed data in response to various access requests of a host. In particular, the memory controller 310 may write data into a selected memory block in response to a secure write command S_Write from the host. If the secure write command S_Write is updating data for previously written secure write data, the memory controller 310 stores currently write-requested updating data in a memory block different from a memory block in which previously written updated data is stored. The memory block in which the previously written updated data is stored is processed by performing a block erase operation after performing a garbage collection operation.

The memory controller 310 stores input updating data in the memory block in which the previously written updated data is stored, according to the secure write command S_Write. In addition, the memory controller 310 may perform garbage collection to copy valid data remaining in a memory block in which the previously written invalidated updated data is stored to another memory block. Then the memory block in which the invalidated updated data was stored is erased.

As a result, the memory controller 310 may erase invalidated secure data such that the invalidated secure data does not remain in the nonvolatile memory device 320 any longer, in response to the secure write command S_Write. Secure performance may be provided without an erase command by such an interface structure of the memory controller 310 during a write operation. In addition, since garbage collection or a block erase operation may be processed as a background operation, a processing command for secure data may be substantially simplified.

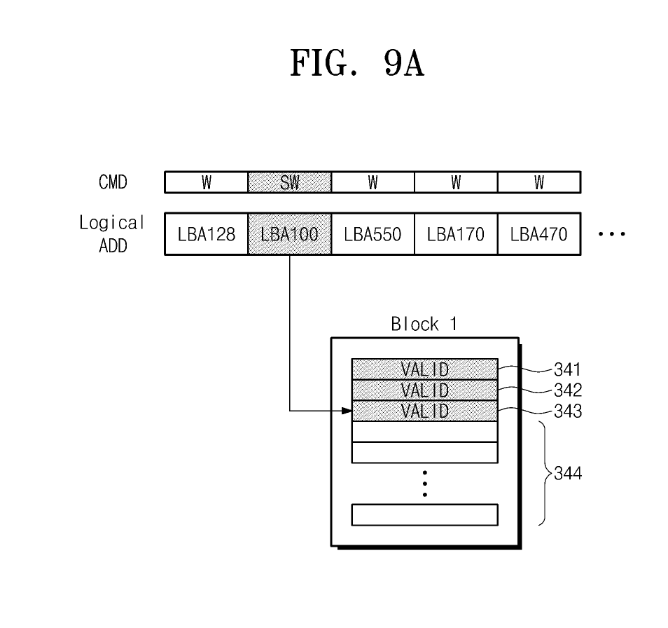

FIG. 8 is a flowchart summarizing a secure write operation performed by the memory controller 310 in FIG. 7, according to at least one example embodiment. The memory controller 310 may perform a secure write operation in response to a secure write command S_Write provided from the host.

The memory controller 310 may receive a write request (S310). For example, data with high security properties may be write-requested by the secure write command S_Write. On the other hand, data that need not be managed in a secure mode may be write-requested using a normal write command Write.

The memory controller 310 detects at least one property of a write command to perform operation branch (S320). When it is determined that the write command is not the secure write command S_Write (No direction), the flow proceeds to S430. When it is determined that the write command corresponds to the secure write command S_Write (Yes direction), the flow proceeds to S440.

The memory controller 310 may control the nonvolatile memory device 320 to program write-requested data into a memory block corresponding to an input logical address LA (S330). The memory controller 310 may provide a command (e.g., S_CMD), data (e.g., DATA), address (e.g., ADD), etc., to the nonvolatile memory device 320 to program the write-requested data into a memory block mapped to the logical address LA provided with the write command.

For example, the memory controller 310 determines whether data write-requested in a secure mode is initial input data or data to update previous input data (S340). When the write-requested data is the data to update the previous input data, logical addresses LA of the previous input data and current input data may be identical to each other. That is, the memory controller 310 may determine whether among previous write-requested data, data having the same logical address as the current write-requested data exists. The determination may be performed with reference to address mapping information managed by the memory controller 310. When it is determined that there is no match between the logical address of the current write-requested data and the logical address of the previous input address, the memory controller 310 may determine that the address is an initial input logical address. Then the flow proceeds to S330. When it is determined that the same logical address as the current input logical address previously existed, the memory controller 310 may determine that the current write request is an update request for the previously written data. Then the flow proceeds to S350.

The memory controller 310 may control the nonvolatile memory device 320 to program updating data into a second memory block different from a first memory block in which previously existing updated data is stored (S350).

The memory controller 310 performs garbage collection on the first memory block in which the updated valid data exists (S360). For example, the memory controller 310 may copy all valid data existing in the first memory block to a third memory block. At this point, a page copy of the updated invalid data does not occur (e.g., the page copy of the updated invalid data is not required).

The memory controller 310 may perform a block erase operation on the first memory block in which all valid data are copied to another memory block and only invalid data exists (S370). The S360 and S370 may each be performed as a background operation.

Hitherto, the description has been concerned with an operating method of a storage device in which a memory block storing previous data is erased during the update of secure data in response to a secure write command S_Write. According to some example embodiments, since the secure data is managed only by a secure write command S_Write, a host need not consider an erasure problem of the secure data.

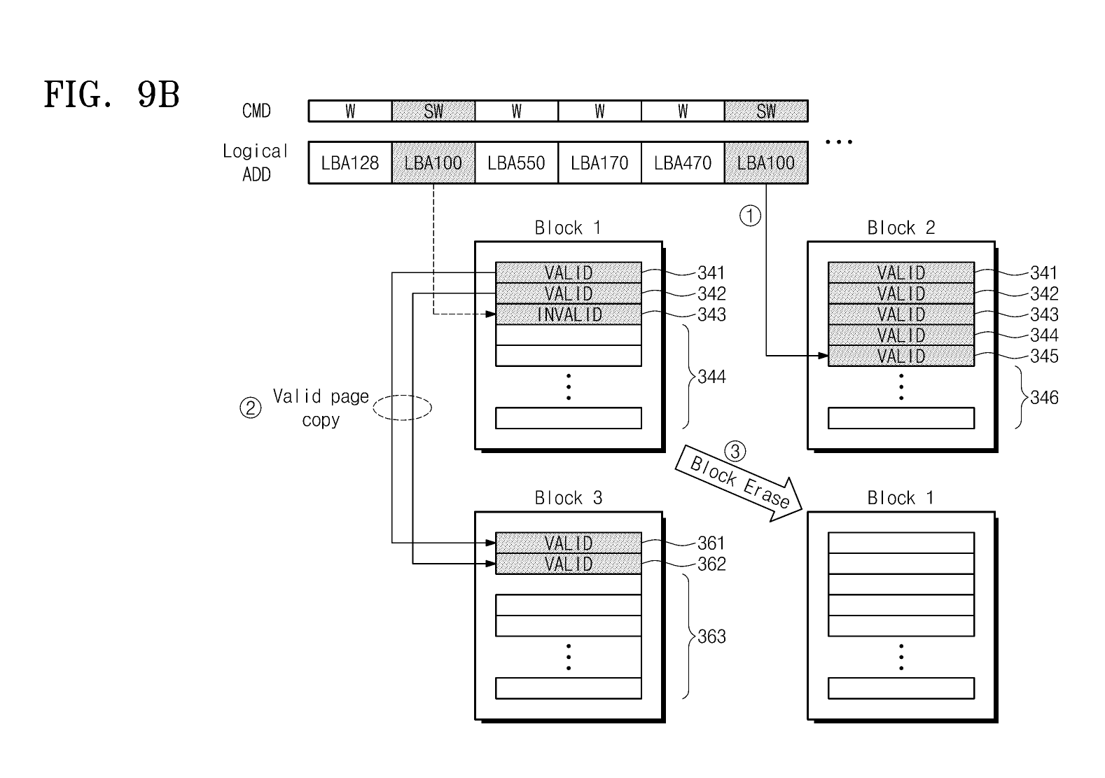

FIGS. 9A and 9B illustrate a data management method described in FIG. 8, according to some example embodiments. FIG. 9A illustrates a procedure of selecting a block when a secure write command is input first, and FIG. 9B illustrates an internal operation of a storage device when a secure write command is input to update previously written data.

Referring to FIG. 9A, when a secure write command SW is provided from the host together with a logical address LBA100, the memory controller 310 writes the secure write command SW into a first memory block Block1 corresponding to the logical address LBA100. Other valid data 341 and 342 may already exist in the first memory block Block1. Empty areas 344 into which data is not written yet may exist in the first memory block Block1.

Referring to FIG. 9B, a secondary secure write command SW and a data write request corresponding to the logical address LBA100 may be generated at an arbitrary or desired time point. Secondarily write-requested data is data to update the data that already exists in the first memory block Block1. Thus, the memory controller 310 writes updating data into a second memory block Block2. Additionally, other valid data 351, 352, 353, and 354 may already exist in the second memory block Block2. Updating data 355 is programmed into the second memory block Block2. This procedure is indicated by the line corresponding to the numeral “1”.

After the updating data is programmed into the second memory block Block2, garbage collection is performed on the first memory block Block1. That is, valid data 341 and 342 existing in the first memory block Block1 are copied to a third memory block Block3. This procedure is indicated by the numeral “2”. A block erase operation is performed on the first memory block Block1. This procedure is indicated by the numeral “3”. Updated data existing in the first memory block Block1 are fully erased by the block erase operation. The erased first memory block Block1 may be immediately used as a free block.

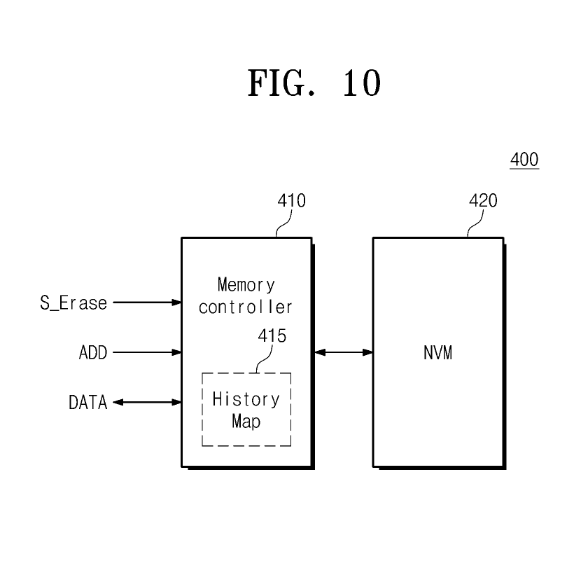

FIG. 10 is a block diagram of a storage device 400 according to at least one example embodiment of the inventive concepts. As illustrated, the storage device 400 may include a memory controller 410 and a nonvolatile memory device 420.

The memory controller 410 may erase erase-requested data and data updated by erase-requested data in response to a secure erase command S_Erase. That is, the memory controller 410 constitutes and manages a history map 415 for the write-requested data when a write request occurs. For example, the memory controller 410 stores and manages a mapping history between a logical address LA of the write-requested data and a physical address of the mapped nonvolatile memory device 420. A plurality of write requests having the same logical address LBA100 may correspond to initial write-requested data and an update request for the initial write-requested data. Accordingly, the memory controller 410 writes and manages the change history of initially written data and a subsequently changed physical address. The change history of the physical address corresponding to the logical address may be stored in the history map 415.

The memory controller 410 performs an erase operation with reference to an address change history stored in the history map 415 when the secure erase command S_Erase is input. That is, when receiving an erase request of data corresponding to a specific and/or desired logical address through the secure erase command S_Erase, the memory controller 410 may control the nonvolatile memory device 420 to erase all invalidated data corresponding to the specific and/or desired logical address. That is, the memory controller 410 may take a measure to erase invalid data of all memory blocks corresponding to the specific and/or desired logical address stored in the history map 415. When invalid data corresponding to the data erase-requested by the secure erase command S_Erase is scattered among a plurality of memory blocks, a block erase operation may be performed on the respective memory blocks.

As a result, the memory controller 410 may erase invalidated secure data in response to the secure erase command S_Erase such that the invalidated secure data does not remain in the nonvolatile memory device 420 any longer. Secure performance may be provided in an erase operation step without a secure write command by the above interface structure of the memory controller 410. Moreover, since garbage collection or a block erase operation may be processed as a background operation, processing instruction for secure data may be substantially simplified.

In addition, the operation of the memory controller 410 performing an erase operation with reference to the history map 415 by the secure erase command S_Erase has been described in FIG. 10. However, it will be understood that the interface of the memory controller 410 may be configured to constitute the history map 415 only in response to a secure write command S_Write.

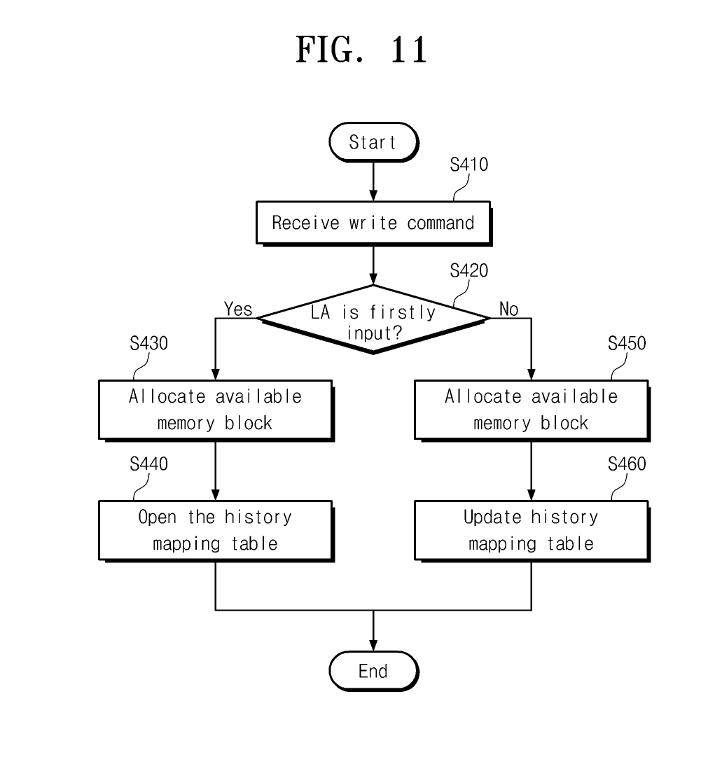

FIG. 11 is a flowchart summarizing a write operation performed by the memory controller 410 in FIG. 10, according to at least one example embodiment. In the case of an update write request, the memory controller 410 generates an address mapping history and stores the address mapping history in the history map 415 (see e.g., FIG. 10) in response to a write command Write provided from a host.

The memory controller 410 may receive a write request (S410). Hint information indicating at least one security property may not be included in a command provided during reception of the write request. That is, creation of the history map 415 may be done with respect to all write requests. In accordance with some example embodiments, data with high security properties may be write-requested by the secure write command S_Write. The history map 415 may be created and updated only in correspondence with the secure write command S_Write. Hereinafter, advantages of at least one example embodiment of the inventive concepts will be described through an example of creating the history map 415 with respect to an overall write command.

The memory controller 410 performs operation branch with reference to a logical address LA provided with a write command (S420). The memory controller 410 may determine whether a current write request is a write request to update previously written data, with reference to the logical address LA. That is, the memory controller 410 may determine whether the logical address LA included in the write command is an initial input logical address that has been never input into the memory controller 410 before. When the logical address LA is the initial input address (Yes direction), the flow proceeds to S430. When the logical address LA is not the initial input address (No direction), the flow proceeds to S450.

The memory controller 410 may allocate a memory block corresponding to the input logical address LA of the write-requested data with reference to an address mapping table (S430). The memory controller 410 may control the nonvolatile memory device 420 to program the write-requested data into the allocated memory block. The memory controller 410 may provide a command (e.g., S_CMD), data (e.g., DATA), address (e.g., ADD), etc., to the nonvolatile memory device 420 to program the write-requested data into the allocated memory block.

The memory controller 410 may create the history map 415 corresponding to the logical address LA of the write-requested data (S440). The memory controller 410 may write a physical address (e.g., block address) corresponding to the logical address LA into the history map 415 and may maintain the written physical address. The history map 415 may be loaded to a working memory, such as a DRAM, an SRAM, and/or other type of volatile memory, incorporated in the memory controller 410. In the nonvolatile memory device 420, the history map 415 may be stored periodically, or when necessary (e.g., on request).

The memory controller 410 may perform an operation to update previously written data (S450). The memory controller 410 may allocate a memory block corresponding to the input logical address LA of the write-requested data with reference to the address mapping table. The memory controller 410 may control the nonvolatile memory device 420 to program the write-requested data into the allocated memory block.

The memory controller 410 may search an item of a logical address LA of current update-requested data from the history map 415 to write a physical address (e.g., block address) in which final updating date is stored into the history map 415 (S460).

Hitherto, the description has been concerned with a method of constituting the history map 415 in response to the write command Write. According to the method, the history map 415 is created with respect to all write commands. However, it will be understood that the history map 415 may be created only in response to the secure write command S_Write.

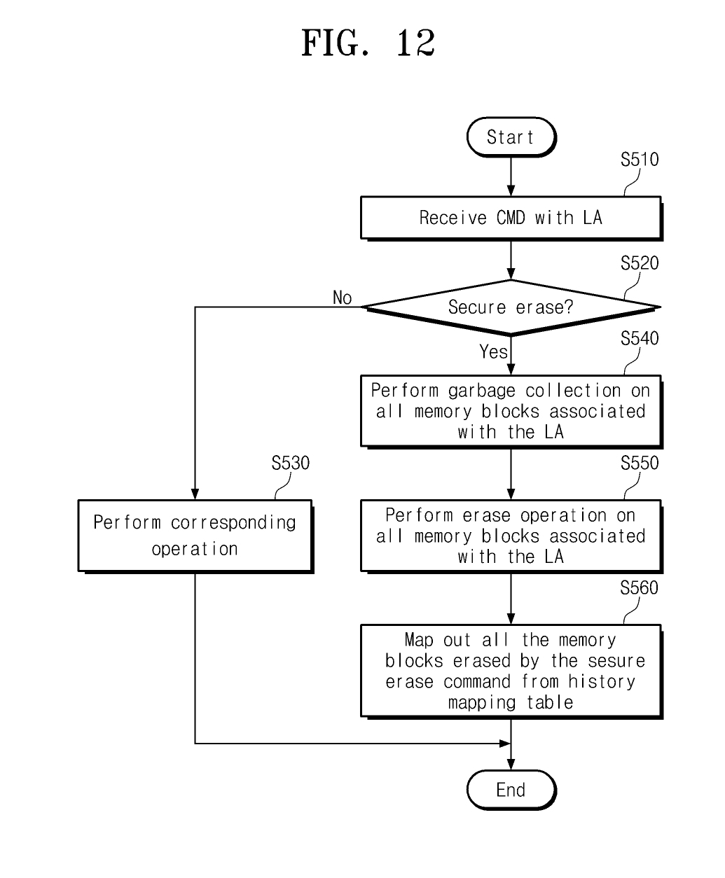

FIG. 12 is a flowchart summarizing a secure erase operation performed by the memory controller 410 in FIG. 10, according to at least one example embodiment. The memory controller 410 may perform a secure erase operation in response to a command provided from the host.

The memory controller 410 may receive a command from the host (S510). When making a request for erasure of specific and/or desired data, the host may determine whether the request is a secure erase request or a normal erase request according to at least one property of the data. For example, the host may request a secure erase command to erase security-requested data. Meanwhile, in the case of data that does not request security, only finally validly managed data may be selectively erased among a plurality of updating data.

The memory controller 410 may detect at least one property of a command to perform operation branch (S520). When an erase command is not a secure erase command S_Erase (No direction), the flow proceeds to S530. When the erase command corresponds to the secure erase command S_Erase (Yes direction), the flow proceeds to S540.

The memory controller 410 may perform a secure erase operation or an overall control operation (S530). For example, the memory controller 410 may perform a memory management operation corresponding to a write command, a read command, etc.

The memory controller 410 may also perform the secure erase operation to erase data erase-requested in a security mode (S540). The memory controller 410 may search an item corresponding to a logical address LA included in a secure write command from the history map 415 (see e.g., FIG. 10). The memory controller 410 performs garbage collection on a memory block associated with a logical address LA of the erase-requested data. For example, the memory controller 410 may perform garbage collection on memory blocks in which valid data or valid data corresponding to the logical address LA exists. That is, valid data existing in the overall memory blocks into which the erase-requested data was written may be copied to another memory block.

After copying valid pages, a block erase operation may be performed on the overall memory blocks corresponding to the logical address LA (S550). Thus, according to the secure erase request, all memory blocks corresponding to the logical address LA may be erased and the erase-requested data does not exist in the nonvolatile memory device 420 any longer.

The memory controller 410 may erase history information associated with data processed by the secure erase command from the history map 415 (S560).

Hitherto, the description has been concerned with the operation of the storage device 400 for a secure erase command provided from the host. That is, when receiving the secure erase command, the storage device 400 applies garbage collection to all memory blocks in which the erase-requested data has been stored before, with reference to history information. The memory controller 410 may perform a block erase operation on these memory blocks to prevent or decrease the erase-requested data from remaining in the nonvolatile memory device 420 in any type.

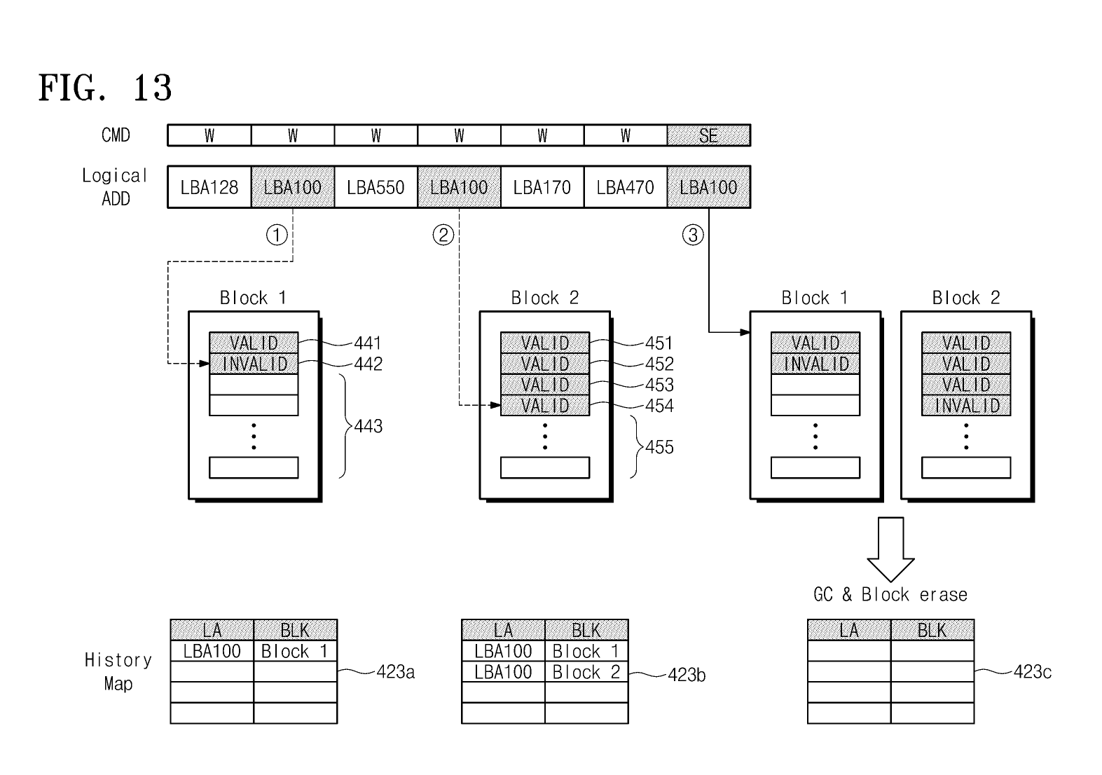

FIG. 13 illustrates a data management method described in FIGS. 11 and 12, according to at least one example embodiment. The features of at least one example embodiment of the inventive concepts will be described through the scenario to provide write commands W including an operation of updating specific or desired data and a secure erase command SE for data subsequently updated once or more times.

A write command W is provided from a host in the corresponding order of logical addresses (LBA128→LBA100→LBA550→LBA100→LBA170→LBA470). An example will be described where a secure erase command SE corresponding to a logical address LBA100 is finally provided. Since this is checked under the standpoint of only updated data, the description will focus on data of the logical address LBA100.

The memory controller 410 writes data into a first memory block Block1 corresponding to the logical address LBA100. This operation is indicated by the dashed line corresponding to the numeral “1”. Write-requested data 442 may be stored in the first memory block Block1. When the data 442 is initially stored in the first memory block Block1, the data 442 may be managed in a valid state. Another valid data 441 may already exist in the first memory block Block1. In addition, empty memory areas 443 into which data is not written yet may exist in the first memory block Block1. Since data corresponding to the logical address LBA100 is initial input data that has never been write-requested before, the memory controller 410 may create a history map 423a. An address (e.g., block address) of the nonvolatile memory device 420 corresponding to the logical address LBA100 is stored in the history map 423a.

When a write request is provided to update the data 442 corresponding to the logical address LBA100, the memory controller 410 may allocate a writable memory block. An example will be described where a second memory block Block2 is allocated to write updating data. This procedure is indicated by the numeral “2”. Then data existing in the first memory block Block1 may change into invalid data and data 454 stored in a second memory block Block2 may become data corresponding to the logical address LBA100. The memory controller 410 may create a history map 423b to add the second block Block2 to a memory block corresponding to the logical address LBA100.

A secure erase command SE of the data corresponding to the logical address LBA100 is provided. As indicated by the numeral “3”, when the secure erase command SE is provided, the memory controller 410 may perform garbage collection GC on the memory blocks Block1 and Block2 written into the history map 423b corresponding to the logical address LBA100. The memory controller 410 may copy valid data existing in the memory blocks Block1 and Block2 to another memory block. The memory controller 410 may control the nonvolatile memory device 420 to perform a block erase operation on the respective memory blocks Block1 and Block2. The memory controller 410 initializes a history map 423c corresponding to the logical address LBA100.

Hitherto, the description has been concerned with a method of maintaining an address history of updated data through a history map and erasing all memory blocks corresponding to a logical address with reference to a history map.

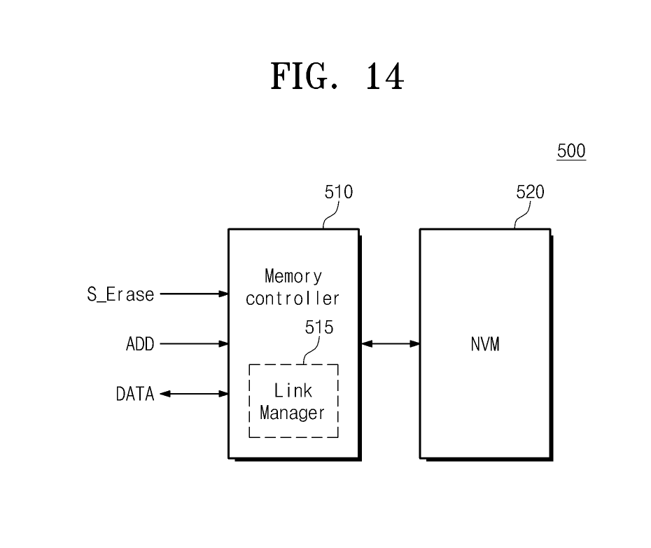

FIG. 14 is a block diagram of a storage device 500 according to at least one example embodiment of the inventive concepts. As illustrated, the storage device 500 may include a memory controller 510 and a nonvolatile memory device 520.

The memory controller 510 includes a link manager 515 that generates and adds link information to each write unit (e.g., page) in response to a write request from a host. The link information includes address information of previously written updated data when write-requested data is data to update previously written data. That is, when data is updated several times at the same logical address, address information of previously written invalidated data is added to each data unit. The link manager 515 may generate and add such link information to a meta-data area of write-requested data. It will be understood that the link manager 515 may be provided as a firmware-type module or may be implemented with special purpose hardware circuitry.

The memory controller 510 may erase both erase-requested data and data updated by the erase-requested data in response to a secure-erase command S_Erase. That is, the memory controller 510 tracks updated data of the erase-requested data with reference to link information of the erase-requested data when receiving the secure erase command S_Erase. The memory controller 510 performs garbage collection and a block erase operation on the overall memory block into which the tracked data are written.

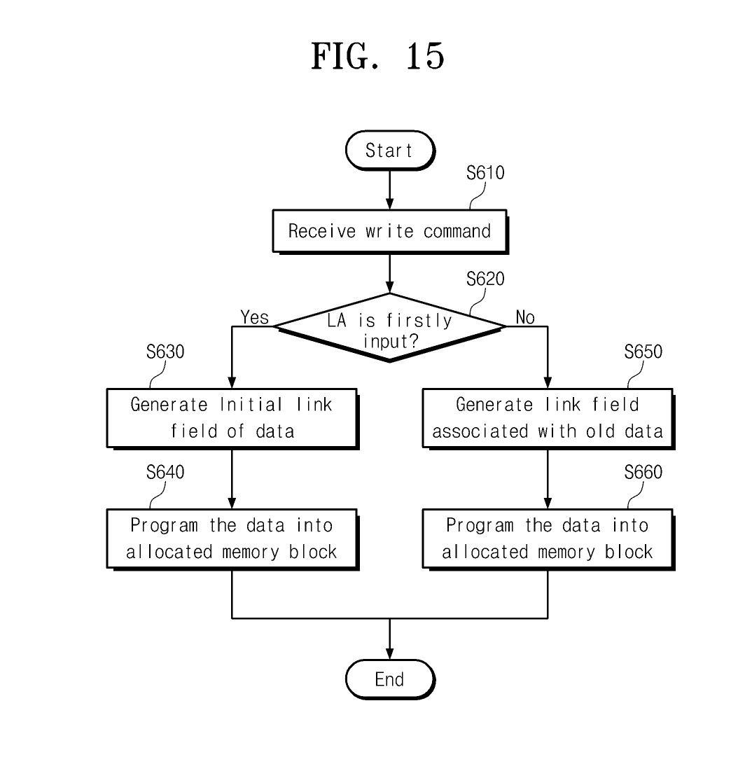

FIG. 15 is a flowchart summarizing a write operation performed in the storage device 500 in FIG. 14, according to at least one example embodiment. The memory controller 500 may create a link field at write-requested data and add link information in response to a write command Write provided from a host.

The memory controller 510 may receive a write request (S610). Hint information to indicate at least one security property may not be included in a command provided during the write request. That is, the link manager 515 may generate link information for all write requests and add the link information to data of a write unit. Additionally, the link manager 515 may generate and add link information only to data write-requested by a secure write command S_Write. Hereinafter, advantages of at least one example embodiment of the inventive concepts will be described through an example of generating and adding link information to the overall write command.

The memory controller 510 may perform operation branch with reference to a logical address LA provided with a write command (S620). The memory controller 510 may determine whether a current write request is a write request to update previously written data, with reference to the logical address LA. That is, the memory controller 510 may determine whether the logical address LA included in the write command is an initial input that has never been input before. When the logical address LA is an initial input address (Yes direction), the flow proceeds to S630. When the logical address LA is not the initial input address (No direction), the flow proceeds to S650.

The link manager 515 of the memory controller 510 may generate link information to indicate that write-requested data is initial write-requested data (S630). The memory controller 510 may perform encoding to add the generated link information to the write-requested data. When the write-requested data is divided into a plurality of write units, such link information may be added to each of the write units.

The memory controller 510 may allocate a memory block into which write data encoded to include the link information is to be written (S640). The memory controller 510 may allocate a memory block corresponding to an input logical address LA with reference to an address mapping table. The memory controller 510 may control the nonvolatile memory device 520 to program the data encoded to include the link information into the allocated memory block.

The memory controller 510 may generate link information including address information of data that the write-requested data updates (S650). The link information is address information on previously written data having the same logical address LA and may be obtained through an address mapping table. The memory controller 510 may perform encoding to add the generated link information to the write-requested data.

The memory controller 510 may allocate a memory block into which the write data encoded to include the link information is to be written (S660). The memory controller 510 may allocate a memory block corresponding to an input logical address LA with reference to the address mapping table. The memory controller 510 may control the nonvolatile memory device 520 to program data including the link information into the allocated memory block.

Hitherto, the description has been concerned with a method of encoding write data to include link information with pre-updated data in response to a write command Write. It will be understood that although the link information may be generated with respect to all write data, the link information may be enabled only when a secure write command S_Write is provided.

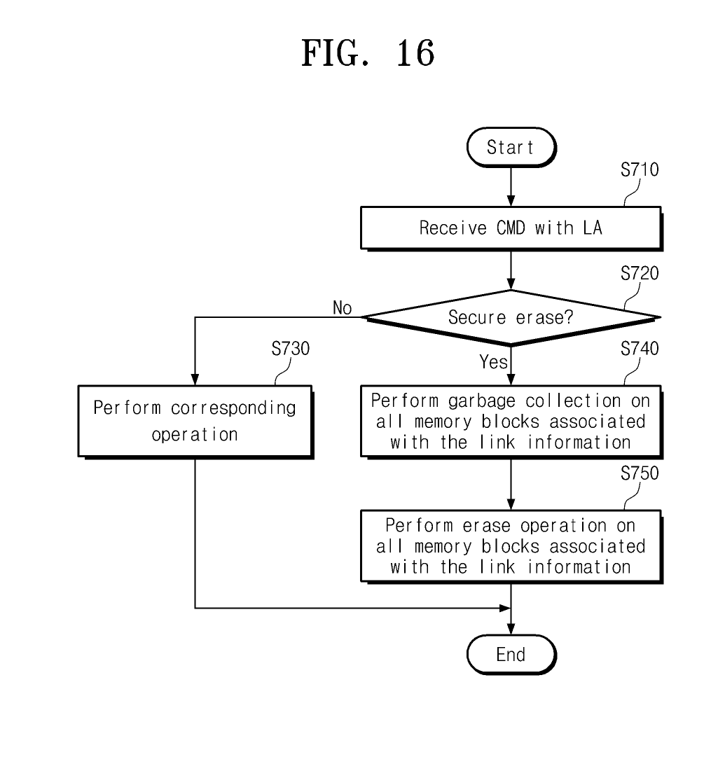

FIG. 16 is a flowchart summarizing a secure erase operation performed in the storage device 500 in FIG. 14, according to at least one example embodiment. The memory controller 510 may perform a secure erase operation in response to a command provided from the host.

The memory controller 510 may receive the command from the host (S710). When specific and/or desired data is erase-requested, the host may determine whether the request is a secure erase request or a normal erase request according to at least one property of the data. For example, in case of data that requests security, the host may request a secure erase command to erase the data. Meanwhile, in the case of data that does not request security, only finally validly managed data may be selectively erased among a plurality of updating data.

The memory controller 510 may detect properties of the command to perform operation branch (S720). When an ease command is not a secure erase command S_Erase (No direction), the flow proceeds to S730. When the erase command is the secure erase command S_Erase (Yes direction), the flow proceeds to S740.

The memory controller 510 may perform a secure erase operation or the overall control operation (S730). For example, the memory controller 510 may perform a memory management operation corresponding to a write command, a read command, etc.

The memory controller 510 may perform a secure erase operation to erase data erase-requested in a secure mode (S740). That is, the memory controller 510 confirms an address of a memory block in which previously written data are stored, using link information of the erase-requested data. The memory controller 510 may perform garbage collection on confirmed memory blocks. For example, the memory controller 510 may perform garbage collection on memory blocks in which valid data or invalid data corresponding to a logical address LA exists. That is, valid data existing in the overall memory blocks into which the erase-requested data was written may be copied to another memory block.

After copying valid pages, a block erase operation is performed on the respective overall memory blocks corresponding to the logical address LA (S750). Thus, according to the secure erase request, the overall memory blocks corresponding to the logical address LA may be erased and the erase-requested data does not exist in the nonvolatile memory device 520 any longer.

Hitherto, the description has been concerned with the operation of the storage device 500 on a secure erase command provided from the host. That is, when the secure erase command is provided, the storage device 500 processes even memory blocks in which invalidated data of the erase-requested data is stored, with garbage collection and a block erase operation with reference to the link information.

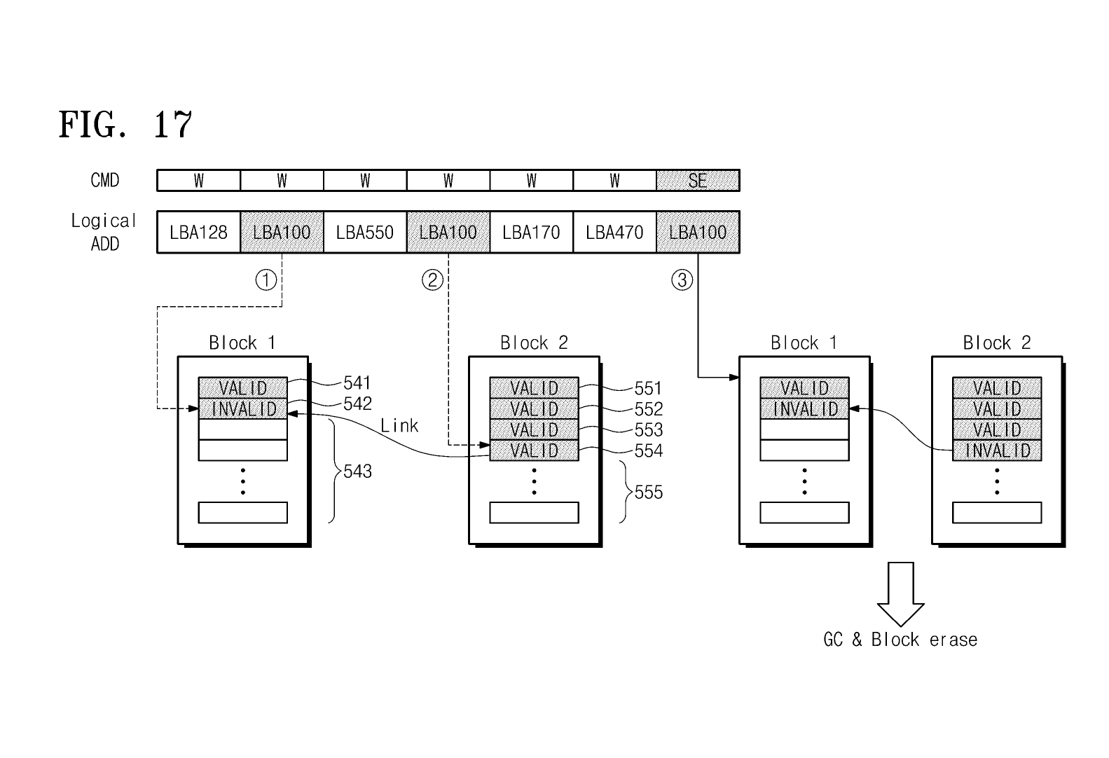

FIG. 17 illustrates a data management method described in FIGS. 15 and 16, according to at least one example embodiment. The features of some example embodiments of the inventive concepts will be described through the scenario to provide write command W including an updating operation on specific or desired data and a secure erase command SE for data subsequently updated once or more times.

A write command W is provided from the host in the corresponding order of logical addresses (LBA128→LBA100→LBA550→LBA100→LBA170→LBA470). An example will be described where a secure erase command SE corresponding to a logical address LBA100 is finally provided. Since this is checked under the standpoint of only updated data, the description will focus on data of the logical address LBA100.

The memory controller 510 performs encoding to generate and add link information to write-requested data. When the write-requested data is not data to update previously written data, the link information may include information to indicate that the write-requested data is initial data. The memory controller 510 writes encoded data into a first memory block Block1 corresponding to the logical address LBA100. This operation is indicated by the dashed line corresponding to numeral “1”. Write-requested data 542 encoded with the link information may be stored in the first memory block Block1. When the write-requested data 542 is initially stored in the first memory block Block1, it may be managed in a valid state. Another valid data 541 may already exist in the first memory block Block1. Empty memory areas 543 into which data is not written yet may exist in the first memory block Block1.

When a write request is provided to update the data 542 stored in the first memory block Block1 corresponding to the logical address LBA100, the memory controller 510 performs encoding to generate and add link information to the write-requested data. Encoded data 554 may be stored in a second memory block Block2. The encoded data 554 may include address information of data 542 invalidated by update.

A secure erase command SE of data corresponding to the logical address LBA100 is provided. As indicated by the dashed line corresponding to numeral “3”, when the secure erase command SE is provided, the memory controller 410 reads link information from valid data corresponding to the logical address LBA100. Address information of the memory blocks Block1 and Block2 in which recent data and updated valid data are stored may be obtained with reference to the link information. The memory controller 510 may perform garbage collection on the overall memory blocks Block1 and Block2 associated with the logical address LBA100. After page copy of valid data, a block erase operation may be performed on the memory blocks Block1 and Block2.

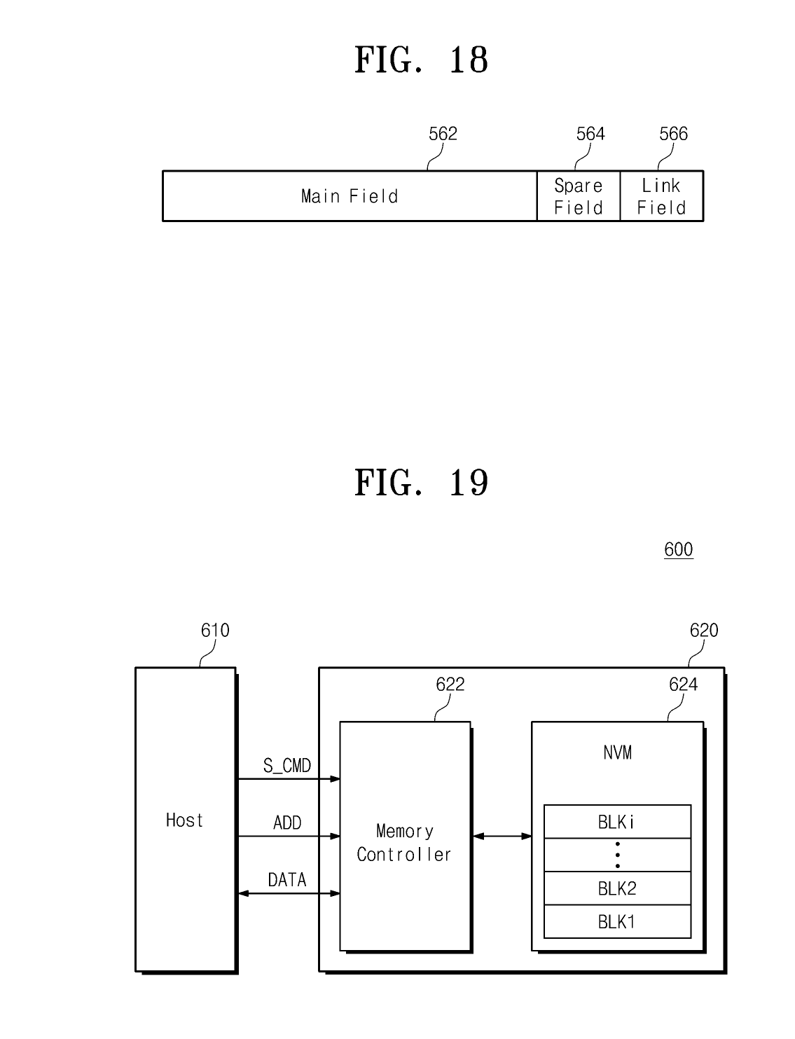

FIG. 18 shows data generated at the memory controller 510 in FIG. 14 through encoding using link information, according to at least one example embodiment. As illustrated, encoded data may include a main field 562, a spare field 564, and a link field 566. User data write-requested at the host may be disposed in the main field 562. Error correction encoding information or various control information on the main field 562 may be disposed in the spare field 564. Link information of data corresponding to the main field 562 may be disposed in the link field 566. The link information may include information on whether the data corresponding to the main field 562 is initial write-requested data or address information of previously written data updated by the data corresponding to the main field 562.

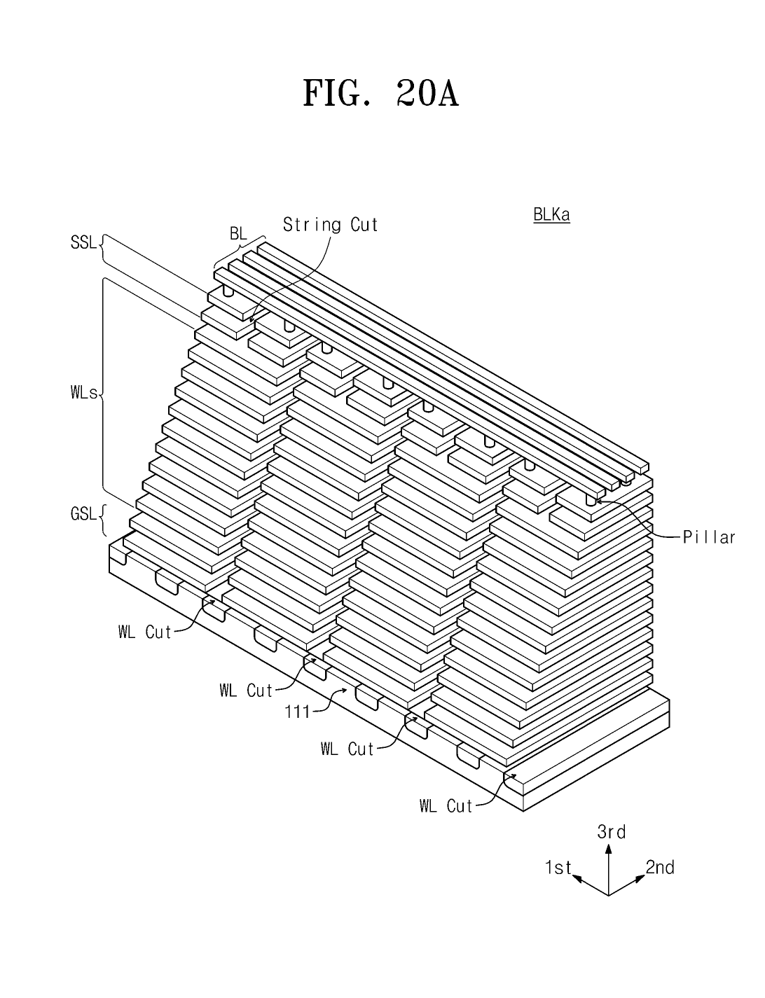

FIG. 19 is a block diagram of a system 6000 according to at least one example embodiment of the inventive concepts. As illustrated, a host 610 may provide a secure command S_CMD and an address ADD to a storage device 620 to exchange data DATA with the storage device 620. The secure command S_CMD may include a secure write command S_Write, a secure erase command S_Erase, etc.

The host 610 may provide the secure write command S_Write, the secure erase command S_Erase, etc., to the storage device 620 to manage secure data. The storage device 620 may operate in response to the secure write command S_Write or the secure erase command S_Erase, based on the features that have been described with reference to FIGS. 1, 6, 7, 10, and 14, respectively.

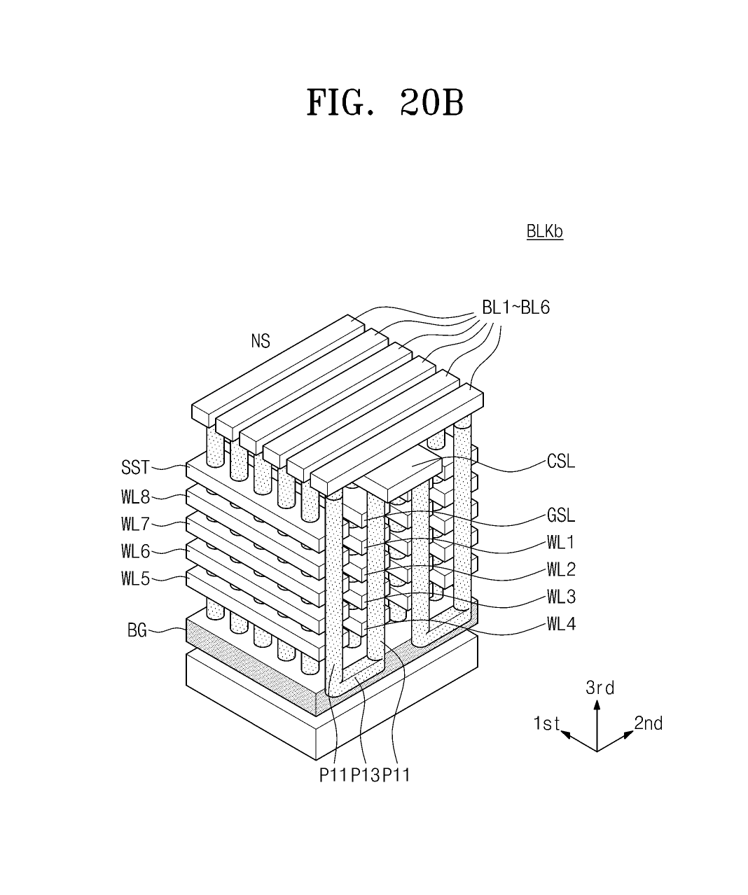

FIGS. 20A and 20B illustrate memory blocks having the form of a three-dimensional cell array included in the nonvolatile memory devices in FIGS. 1, 6, 7, 10, and 14, according to some example embodiments.

Referring to FIG. 20A, a memory block BLKa may include at least four sub-blocks formed on a substrate. Each of the sub-blocks is formed by stacking at least one ground selection line GSL, a plurality of wordlines WLs, and at least one string selection line SSL on the substrate and between wordline cuts in the form of a plate. The at least one string selection line SSL may be separated by string selection line cuts. Although a string selection line cut exists in the memory block BLKa, a memory block according to inventive concepts is not limited thereto. A memory block according to some example embodiments may be implemented such that a string selection line does not exist therein.

At least one dummy wordline may be stacked between the ground selection line GSL and the wordlines WLs in the form of a plate, or at least one dummy wordline may be stacked between the wordlines WLs and the string selection line SSL. Although not shown in FIG. 20A, each of the wordline cuts includes a common source line CSL. In some example embodiments, common source lines CSL included in the respective wordline cuts are commonly connected. A pillar connected to a bitline penetrates the at least one ground selection line GSL, the wordlines WLs, and the at least one string selection line SSL to form a string.

As show in FIG. 20A, a target between wordline cuts is a sub-block. However, example embodiments of the inventive concepts are not limited thereto. According to some example embodiments, a target between a wordline cut and a string selection line cut may be defined as a sub-block. The memory block BLKa may be implemented with a merged wordline structure where two wordlines are merged into one.

FIG. 20B shows a memory block BLKb according to at least one example embodiment of the inventive concepts. For convenience of description, it is assumed that the number of wordline layers is four, however example embodiments are not limited thereto. Referring to FIG. 20B, a memory block is implemented using a pipe-shaped bit cost scalable (PBiCS) structure where lower ends of adjacent memory cells connected in series are connected by a pipe. A memory block BLKb includes strings NS of m×n (m and n being positive integers).

In FIG. 20B, m=6 and n=2. Each of the strings NS includes serially connected memory cells MC1 to MC8. First upper ends of the memory cells MC1 to MC8 are connected to a string selection transistor SST, and second upper ends of the memory cells MC1 to MC8 are connected to a ground selection transistor GST. Lower ends of the memory cells MC1 to MC8 are pipe-connected.

Memory cells constituting a string NS are stacked on a plurality of semiconductor layers to be formed. Each string NS includes a first pillar PL11, a second pillar PL12, and a pillar connection portion PL13 connecting the first and second pillars PL11 and PL12 to each other. The first pillar PL11 is connected to a bitline (e.g., BL1) and the pillar connection portion PL13 and is formed through the string select line SSL and wordlines WL5 to WL8. The second pillar PL12 is connected to the pillar connection portion PL13 and is formed through wordlines WL1 to WL4. As shown in FIG. 20B, the string NS is implemented with a U-shaped pillar.

In some example embodiments, a back-gate BG may be formed on a substrate and the pillar connection portion PL13 may be implemented in the back-gate BG. In example embodiments, the back-gate BG may commonly exist in the blocks BLK0 to BLKz. The back-gate BG may be isolated from a back-gate of another block.

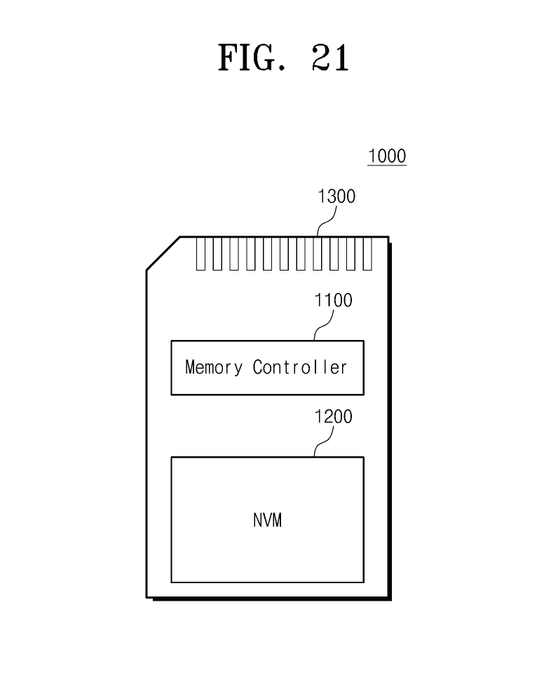

FIG. 21 is a block diagram of a memory card system 1000 to which a nonvolatile memory system according to at least one example embodiment of the inventive concepts. As illustrated, the memory card system 1000 includes a controller 1100, a nonvolatile memory 1200, and a connector 1300.

The controller 1100 is connected to the nonvolatile memory 1200. The controller 1100 is configured to access the nonvolatile memory 1200. For example, the controller 1100 is configured to control read, write, erase, and background operations. The background operation includes operations such as wear-level management and garbage collection. In some example embodiments, the controller 1100 may manage secure data based on the methods described with reference to FIGS. 1 to 19.

The controller 1200 is configured to provide an interface between the nonvolatile memory 1100 and the host. The controller 1200 is configured to drive firmware for controlling the nonvolatile memory 1100. The controller 1100 may include components such as a random access memory (RAM), a processing unit, a host interface, a memory interface, and an error correction unit.

The controller 1100 may communicate with an external device through the connector 1300. The controller 1100 may communicate with an external device (e.g., host) using a specific and/or desired interface protocol. In some example embodiments, the controller 1200 is configured to an external device using at least one of various interface protocols such as USB (Universal Serial Bus), MMC (multimedia card), eMMC (embedded MMC), PCI (peripheral component interconnection), PCI-E (PCI-express), ATA (Advanced Technology Attachment), Serial-ATA, Parallel-ATA, SCSI (small computer small interface), ESDI (enhanced small disk interface), IDE (Integrated Drive Electronics), Firewire, UFS (Universal Flash Storage), NVMe (Nonvolatile Memory express), etc. In some example embodiments, a write command defined by the above interface protocols may include size information of the write data.

The nonvolatile memory 1200 may be implemented with various nonvolatile memory devices such as an electrically erasable and programmable ROM (EPROM), a NAND flash memory, a NOR flash memory, a phase-change RAM (PRAM), a resistive RAM (ReRAM), a ferroelectric RAM (FRAM), a spin-torque magnetic RAM (STT-MRAM), etc.

In some example embodiments, the controller 1100 and the nonvolatile memory 1200 may be integrated into a single semiconductor device. In some example embodiments, the controller 1200 and the nonvolatile memory 1100 may be integrated into a single semiconductor device to constitute a solid state drive (SSD). The controller and the nonvolatile memory 1200 may also be integrated into a single semiconductor device to constitute a memory card. For example, the controller 1100 and the nonvolatile memory 1200 may be integrated into a single semiconductor device to constitute a memory card such as a personal computer memory card international association (PCMCIA), a compact flash card (CF), a smart media card (SM, SMC), a memory stick, a multimedia card (MMC, RS-MMC, and MMCmicro), a SD card (SD, miniSD, and microSD), a universal flash memory device (UFS), etc.

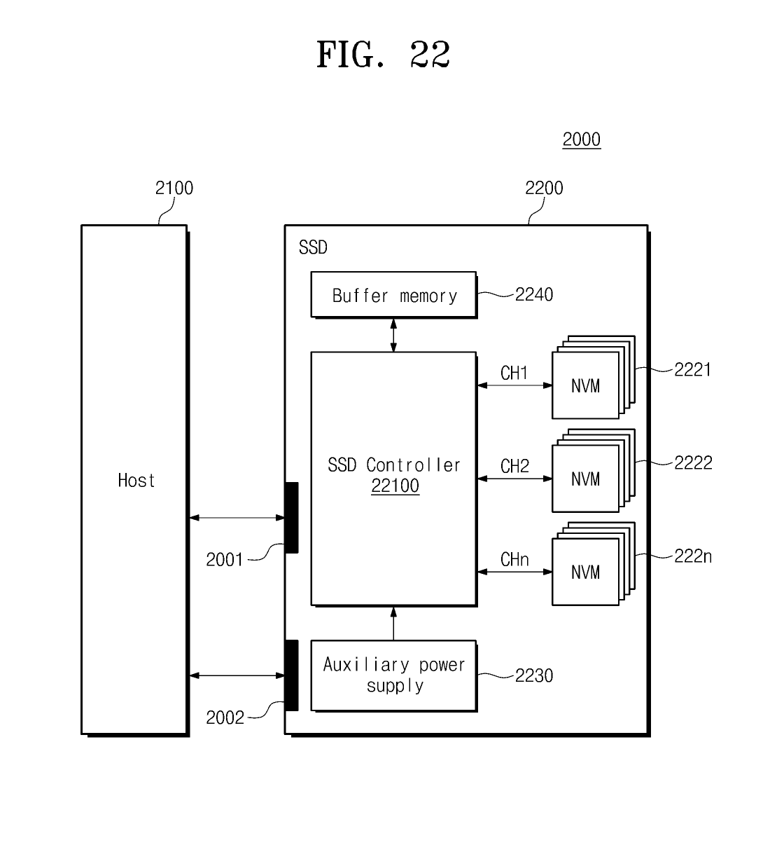

FIG. 22 is a block diagram of a solid state drive (SSD) system 2000 to which a nonvolatile memory system according to at least one example embodiment of the inventive concepts. As illustrated, the SSD system 2000 includes a host 2100 and an SSD 2200. The SSD 2200 transmits/receives a signal SIG to/from the host 2100 through a signal connector 2001 and is supplied with power PWR through a power connector 2002.

The SSD 2200 includes an SSD controller 2210, a plurality of flash memories 2221 to 222n, an auxiliary power supply 2230, and a buffer memory 2240.

The SSD controller 2210 may control the flash memories 2221 to 222n in response to the signal SIG received from the host 2100. In some example embodiments, the SSD controller 2210 may operate based on the methods described with reference to FIGS. 1 to 19.

The auxiliary power supply 2230 is connected to the host 2100 through the power connector 2002. The auxiliary power supply 2230 may be supplied with the power PWR from the host 2100. The auxiliary power supply 2230 may supply power of the SSD system 2000 when power is not sufficiently supplied from the host 2100. In some example embodiments, the auxiliary power supply 2230 may be disposed inside or outside the SSD 2200. For example, the auxiliary power supply 2230 may be disposed on a mainboard and may supply auxiliary power to the SSD 2200.

The buffer memory 2240 serves as a buffer memory of the SSD 2200. For example, the buffer memory 2240 may temporarily store data received from the host 2100 or data received from the flash memories 2221 to 222n, or may temporarily store metadata (e.g., mapping table) of the flash memories 2221 to 222n. The buffer memory 2240 may include a nonvolatile memory such as DRAM, SDRAM, DDR SDRAM, LPDDR SDRAM, SRAM, etc., and nonvolatile memories such as FRAM ReRAM, STT-MRAM, PRAM, etc.

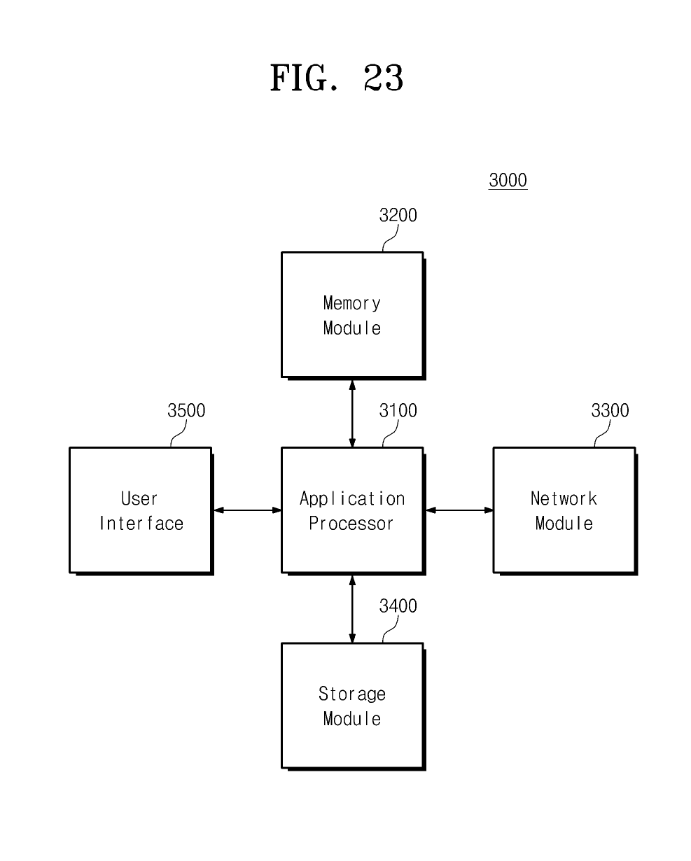

FIG. 23 is a block diagram of a user system 3000 to which a nonvolatile memory system according to at least one example embodiment of the inventive concepts. As illustrated, the user system 3000 includes an application processor 3100, a memory module 3200, a network module 3300, a storage module 3400, and a user interface 3500.

The application processor 3100 may drive components included in the user system 3000 and an operating system (OS). In some example embodiments, the application processor 3100 may include controllers to control the components included in the user system 3000, interfaces, and a graphic engine. The application processor 3100 may be provided as a system-on-chip (SoC).

The memory module 3200 may function as a main memory, a working memory, a buffer memory or a cache memory of the user system 3000. The memory module 3200 may include a volatile random access memory such as DRAM, SDRAM, DDR SDRAM, DDR2 SDRAM, DDR3 SDRAM, LPDDR SDARM, LPDDR3 SDRAM, LPDDR3 SDRAM, etc., or a nonvolatile random access memory such as PRAM, ReRAM, MRAM, FRAM, etc. In some example embodiments, the memory module 3200 may be packaged with the application processor 3100 in a package-on-package (PoP) architecture.

The network module 3300 may communicate with external devices. For example, the network module 3300 may support wireless communication protocols such as CDMA (Code Division Multiple Access), GSM (Global System for Mobile communication), WCDMA (wideband CDMA), CDMA-2000, TDMA (Time Division Multiple Access), LTE (Long Term Evolution), Wimax, WLAN, UWB, Bluetooth, WI-DI, etc. In some example embodiments, the network module 3300 may be included in the application processor 3100.

The storage module 3400 may store data. For example, the storage module 3400 may store data received from the application processor 3100. Additionally, the storage module 3400 may transmit data stored in the storage module 3400 to the application processor 3100. In some example embodiments, the storage module 3400 may be implemented with a nonvolatile semiconductor memory device such as a phase-change RAM (PRAM), a magnetic RAM (MRAM), a resistive RAM (ReRAM), a NAND flash memory, a NOR flash memory, a three-dimensional (3D) NAND flash memory, etc.

In some example embodiments, the storage module 3400 may operate based on the operating methods described with reference to FIGS. 1 to 19. The storage module 3400 may communicate with the application processor 3100 based on a desired (and/or alternatively predetermined) interface. The storage module 3400 may adjust execution time of garbage collection based on a write command received from the application processor 3100.

The user interface 3500 may include interfaces that input data or a command to the application processor 3100 or output data to an external device. For example, the user interface 3500 may include user input interfaces such as a keyboard, a keypad, a button, a touch panel, a touch screen, a touch pad, a touch ball, a camera, a microphone, a gyroscope sensor, a vibration sensor, etc. The user interface 3500 may include user output interfaces such as a liquid crystal display (LCD), an organic light emitting diode (OLED) display, an active matrix OLED (AMOLED), an LED, a speaker, a monitor, etc.

The above-described nonvolatile memory device or memory controller may be packaged in various types of packages. For example, the nonvolatile memory 1200 or the memory card system 1000 may be packaged in various types of packages such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline IC (SOIC), shrink small outline package (SSOP), thin small outline package (TSOP), system in package (SIP), multi-chip package (MCP), wafer-level fabricated package (WFP), wafer-level processed stack package (WSP), etc.

It should be understood that example embodiments described herein should be considered in a descriptive sense only and not for purposes of limitation. Descriptions of features or aspects within each device or method according to example embodiments should typically be considered as available for other similar features or aspects in other devices or methods according to example embodiments. While some example embodiments have been particularly shown and described, it will be understood by one of ordinary skill in the art that variations in form and detail may be made therein without departing from the spirit and scope of the claims.

What is claimed is:

1. An operating method of a storage device including a nonvolatile memory device, the operating method comprising:
receiving a logical address corresponding to the nonvolatile memory device and a write command for first data from an external device;
determining whether the write command includes at least one security property;
detecting whether second data is stored in the received logical address of the nonvolatile memory device, based on a result of the determination; and
writing the first data into a unit memory area of the nonvolatile memory device in which the second data is stored, based on a result of the detection.

2. The operating method as set forth in claim 1, wherein the unit memory area corresponds to an erase-unit memory area of the nonvolatile memory device.

3. The operating method as set forth in claim 2, wherein the erase-unit memory area corresponds to a memory block of the nonvolatile memory device.

4. The operating method as set forth in claim 1, wherein
the first data is data to update the second data; and
the second data is invalidated.

5. The operating method as set forth in claim 1, further comprising:
receiving an erase command for the first data from the external device.

6. The operating method as set forth in claim 5, further comprising:
performing a block erase operation on the erase-unit memory area of the nonvolatile memory device in response to the receiving the erase command for the first data.

7. The operating method as set forth in claim 5, wherein the erase command includes information to indicate at least one security property.

8. The operating method as set forth in claim 1, wherein the nonvolatile memory device includes a separate secure memory area configured to store the first data or the second data.

9. The operating method as set forth in claim 1, wherein the first data is written into an arbitrary programmable memory block of the nonvolatile memory device when the write command does not include the at least one security property.

10. The operating method as set forth in claim 1, wherein the nonvolatile memory device includes a three-dimensional memory array, the three-dimensional memory array including a charge trap layer.

11. A storage device comprising:
a nonvolatile memory device; and
a memory controller configured to control the nonvolatile memory device,
the memory controller is configured to,
store and update data write-requested and update-requested by a secure write command from an external device using a logical address corresponding to the nonvolatile memory device, and
perform a block erase operation on the memory block of the nonvolatile memory device in response to an erase command for the data.

12. The storage device as set forth in claim 11, wherein the erase command is a secure erase command to erase data including at least one security property.

13. The storage device as set forth in claim 11, wherein the memory block is erased on the nonvolatile memory device in response to the erase command for the data without performing garbage collection.

14. The storage device as set forth in claim 11, wherein the nonvolatile memory device includes a plurality of three-dimensionally stacked memory blocks.

15. A nonvolatile storage device comprising:
a nonvolatile memory device; and
a memory controller configured to,
receive at least one data operation command and a logical address associated with the at least one command from an external device, the at least one data operation command and the logical address related to the nonvolatile memory device,
determine whether the received at least one data operation command indicates that a secure data operation is requested, and
perform the secure data operation at the received logical address of the nonvolatile memory device in accordance with the results of the determination.

16. The nonvolatile storage device of claim 15, wherein
the nonvolatile memory device further includes at least one secure memory block area and at least one non-secure memory block area; and
the secure data operation includes at least one of a secure write command, a secure update command, and a secure erase command.

17. The nonvolatile storage device of claim 16, wherein the memory controller is further configured to determine whether the secure data operation is a secure write command or a secure update command by determining whether the received logical address corresponds to a previously received logical address related to a secure write command.

18. The nonvolatile storage device of claim 16, wherein the memory controller is further configured to:
receive data from the external device corresponding to the received at least one data operation command when the received at least one data operation command is a secure write command or a secure update command;
write the received data in the at least one secure memory block area; and
update a memory address mapping history associated with the memory controller with a physical location of the data written in the at least one secure memory block area.

19. The nonvolatile storage device of claim 16, wherein the memory controller is further configured to:
receive data from the external device corresponding to the received at least one data operation command when the received at least one data operation command is a secure update command;
write the received data in the at least one secure memory block area;
erase data stored at a previous physical address associated with the received logical address; and
update a memory address mapping history associated with the memory controller with a new physical location of the data written in the at least one secure memory block area.

20. The nonvolatile storage device of claim 16, wherein the memory controller is further configured to erase data corresponding to the received logical address from the at least one secure memory block area when the secure data operation is a secure erase command, and update a memory address mapping history associated with the memory controller in accordance with the results of the erase operation.
